(19) United States
(12) Patent Application Publication
(10) Pub. No.: US 2011/0187419 A1
(43) Pub. Date: Aug. 4, 2011

(54) SEMICONDUCTOR INTEGRATED CIRCUIT AND VOLTAGE CONTROLLER THEREWITH

(75) Inventors: Yoshifumi Ikenaga, Kanagawa (JP); Masahiro Nomura, Kanagawa (JP)

(73) Assignee: Renesas Electronics Corporaiton

(21) Appl. No.: 13/017,268

(22) Filed: Jan. 31, 2011

(30) Foreign Application Priority Data
Feb. 2, 2010 (JP) 2010-021471

(51) Int. Cl. H03B 19/00; G05F 1/10

(52) U.S. Cl. 327/117; 327/540

(57) ABSTRACT

A semiconductor integrated circuit is capable of accurately detecting the characteristics of a chip. The semiconductor integrated circuit includes a monitor circuit and a control circuit. The control circuit generates a clock pulse signal having M successive pulses (M is 2 or a greater integer), and outputs the clock pulse signal to the monitor circuit. The monitor circuit includes a frequency divider and a ring oscillator. The frequency divider frequency divides the clock pulse signal by M and generates the resulting signal as an enable signal. The ring oscillator generates an oscillation signal as a monitor output value during a period defined in accordance with the enable signal.

### CROSS-REFERENCE TO RELATED APPLICATION

The disclosure of Japanese Patent Application No. 2010-21471 filed on Feb. 2, 2010 including the specification, drawings, and abstract is incorporated herein by reference in its entirety.

### BACKGROUND

1. Field of the Invention

The present invention relates to a semiconductor integrated circuit and a voltage controller therewith, and more particularly, to a semiconductor integrated circuit that detects the characteristics of a chip.

2. Description of Related Art

The power consumption of a semiconductor integrated circuit using a complementary metal oxide semiconductor (CMOS) logic gate can be reduced, for instance, by dynamic voltage and frequency scaling (DVFS). DVFS is a technique for controlling a supply voltage in accordance with a demanded operation speed. DVFS can be implemented by using a delay monitor. The delay monitor detects whether the operation speed of a chip has reached a reference value. Therefore, the delay monitor needs to accurately detect the characteristics of the chip that are dependent on process level, temperature, and supply voltage.

A semiconductor integrated circuit using a delay monitor is disclosed in Japanese Unexamined Patent Publication No. 2008-180635. The delay monitor includes a ring oscillator and counts the number of oscillations of the ring oscillator during a predetermined period. Thus, a semiconductor integrated circuit based on a conventional technology can detect gate delay with the delay monitor and without using a temperature sensor or a voltage sensor. In other words, the semiconductor integrated circuit based on the conventional technology can detect variations in the characteristics of an element in a chip with the delay monitor.

A semiconductor integrated circuit using a monitor circuit or a speed monitor circuit is disclosed in Japanese Unexamined Patent Publications No. 2002-100967 and 2005-045172.

### SUMMARY

For example, the conventional technology outputs average variations in the characteristics of an element in a chip by averaging the output results (counts) of plural delay monitors (monitor circuits) disposed in the chip. Particularly, the conventional technology can easily detect the characteristics of the chip because it causes the delay monitors to output resulting digital values (counts).

In order to detect the characteristics of the chip with high accuracy, the delay monitors need to perform a counting operation at the same time. More specifically, the ring oscillators in the delay monitors need to oscillate at the same time. Therefore, control signals (oscillator enable signals) supplied to the delay monitors to control the oscillation time of the ring oscillators need to have the same ON period. As such being the case, the conventional technology handles a one-clock cycle of a reference clock as the ON period in order to avoid the influence of a skew between the rise and fall of the control signals.

When the conventional technology is used, the ON periods of the control signals are determined in accordance with the reference clock and a measurement start signal. More specifically, during the use of the conventional technology, a control signal (oscillator enable signal) in the ON state is generated by allowing a flip-flop to detect a high-level measurement start signal in synchronism with the reference clock. As described above, when the conventional technology is used, two signal wires handling the reference clock and the measurement start signal are used in each delay monitor to generate a control signal. Therefore, if there is a significant skew between the reference clock and the measurement start signal, the control signals supplied to the individual delay monitors may differ in the ON period. That is why the conventional technology cannot accurately detect the characteristics of the chip.

According to an embodiment of the present invention, there is provided a semiconductor integrated circuit including a first monitor circuit and a control circuit. The control circuit generates a control signal having M successive pulses (M is 2 or a greater integer) and outputs the control signal to the first monitor circuit. The first monitor circuit includes a frequency divider circuit and an oscillator circuit. The frequency divider circuit frequency-divides the control signal by M and generates the resulting signal as an enable signal. The oscillator circuit generates an oscillation signal as a monitor output value during a period defined in accordance with the enable signal.

As the above-described circuit configuration is employed, the characteristics of a chip can be accurately detected.

The present invention makes it possible to provide a semiconductor integrated circuit that is capable of accurately detecting the characteristics of a chip.

### BRIEF DESCRIPTION OF THE DRAWINGS

Embodiments of the present invention will be described in detail based on the following figures, wherein:

FIG. 1 is a diagram illustrating a semiconductor integrated circuit according to a first embodiment of the present invention;

FIG. 2 is a diagram illustrating a control circuit according to the first embodiment of the present invention;

FIG. 3 is a diagram illustrating a monitor circuit according to the first embodiment of the present invention;

FIG. 4 is a diagram illustrating a summing circuit according to the first embodiment of the present invention;

FIG. 5 is a timing diagram illustrating an operation of the semiconductor integrated circuit according to the first embodiment of the present invention;

FIG. 6 is a diagram illustrating the semiconductor integrated circuit according to the first embodiment of the present invention;

FIG. 7 is a diagram illustrating the monitor circuit according to the first embodiment of the present invention;

FIG. 8 is a timing diagram illustrating an operation of the semiconductor integrated circuit according to the first embodiment of the present invention;

FIG. 9 is a diagram illustrating the monitor circuit according to the first embodiment of the present invention;

FIG. 10 is a timing diagram illustrating an operation of the semiconductor integrated circuit according to the first embodiment of the present invention;

FIG. 11 is a timing diagram illustrating an operation of the semiconductor integrated circuit according to the first embodiment of the present invention;

FIG. 12 is a diagram illustrating the semiconductor integrated circuit according to a second embodiment of the present invention;

FIG. 13 is a diagram illustrating the monitor circuit according to the second embodiment of the present invention;

FIG. 14 is a timing diagram illustrating an operation of the semiconductor integrated circuit according to the second embodiment of the present invention;

FIG. 15 is a diagram illustrating the semiconductor integrated circuit according to a third embodiment of the present invention;

FIG. 16 is a diagram illustrating the monitor circuit according to the third embodiment of the present invention;

FIG. 17 is a diagram illustrating the summing circuit according to the third embodiment of the present invention;

FIG. 18 is a timing diagram illustrating an operation of the semiconductor integrated circuit according to the third embodiment of the present invention;

FIG. 19 is a diagram illustrating the semiconductor integrated circuit according to a fourth embodiment of the present invention;

FIG. 20 is a diagram illustrating the monitor circuit according to the fourth embodiment of the present invention;

FIG. 21 is a diagram illustrating the summing circuit according to the fourth embodiment of the present invention;

FIG. 22 is a timing diagram illustrating an operation of the semiconductor integrated circuit according to the fourth embodiment of the present invention;

FIG. 23 is a diagram illustrating the monitor circuit according to the fourth embodiment of the present invention;

FIG. 24 is a diagram illustrating the monitor circuit according to a fifth embodiment of the present invention;

FIG. 25 is a diagram illustrating the semiconductor integrated circuit according to a sixth embodiment of the present invention;

FIG. 26 is a diagram illustrating a voltage control circuit according to the sixth embodiment of the present invention;

FIG. 27 is a diagram illustrating the semiconductor integrated circuit according to a seventh embodiment of the present invention;

FIG. 28 is a diagram illustrating the voltage control circuit according to the seventh embodiment of the present invention; and

FIG. 29 is a timing diagram illustrating an operation of the semiconductor integrated circuit according to the seventh embodiment of the present invention.

### DETAILED DESCRIPTION OF THE PREFERRED EMBODIMENTS

Embodiments of the present invention will now be described in detail with reference to the accompanying drawings. For clarity of explanation, redundant descriptions will be omitted as appropriate.

### First Embodiment

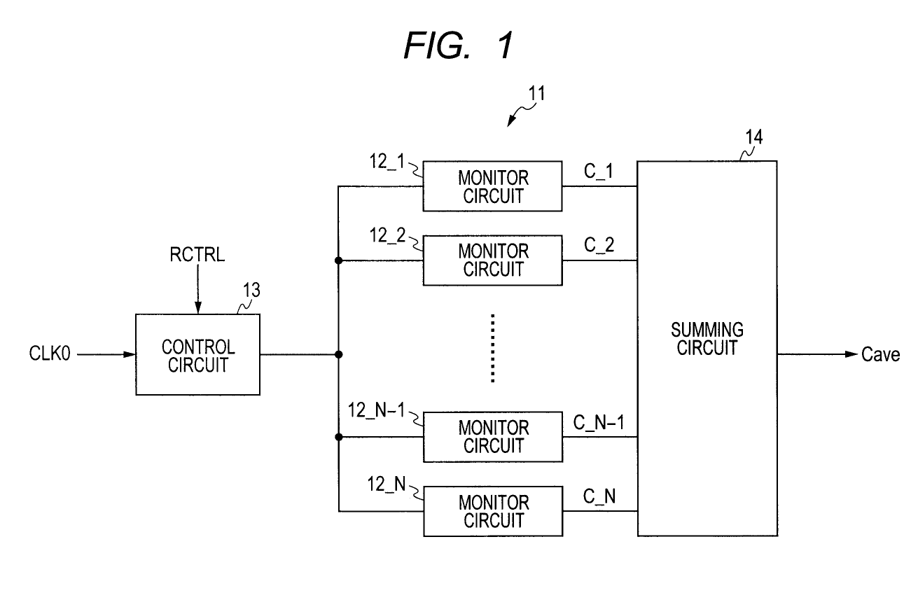

FIG. 1 is a block diagram illustrating a semiconductor integrated circuit 11 according to a first embodiment of the present invention. The circuit shown in FIG. 1 includes monitor circuits 12_1 to 12_N, a control circuit 13, and a summing circuit 14. N is equal to the k-th power of 2 (k is 0 or a greater integer).

The control circuit 13 inputs a clock signal CLK0 and a control signal RCTRL, and outputs a reset signal RE and a clock pulse signal EN_PULSE to the monitor circuits 12_1 to 12_N. The monitor circuits 12_1 to 12_N output their respective counts C_1 to C_N to the summing circuit 14. The summing circuit 14 outputs an average count C_{AVE}, which is the average of the counts C_1 to C_N. The monitor circuits 12_1 to 12_N are adapted to detect the characteristics of a chip that are dependent on process level, temperature, and supply voltage.

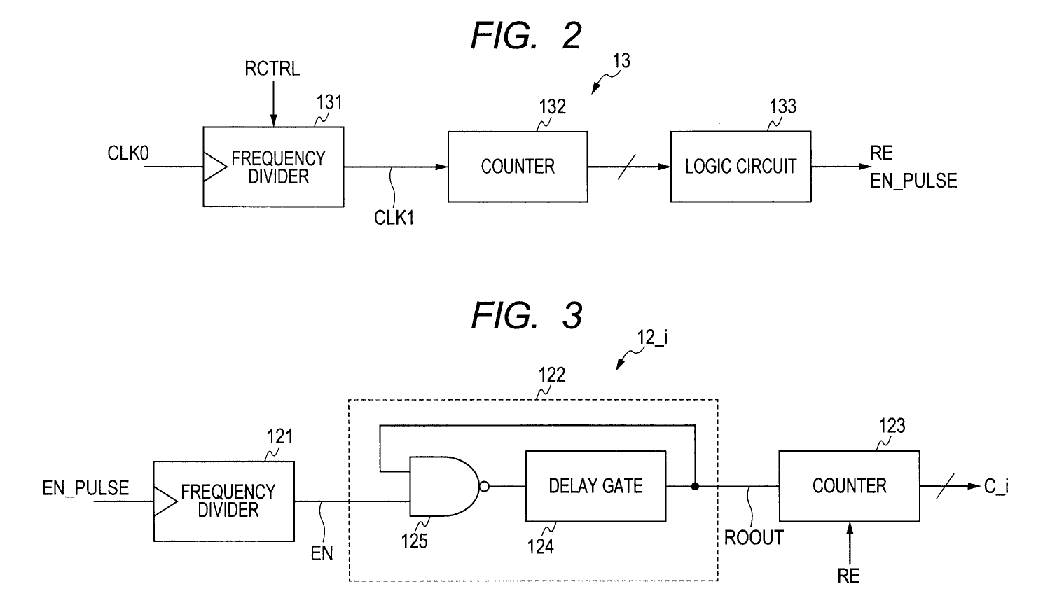

FIG. 2 shows the circuit configuration of the control circuit 13. The control circuit includes a frequency divider 131, a counter 132, and a logic circuit 133. The frequency divider 131 obtains a clock signal CLK1 by frequency-dividing the clock signal CLK0 having a cycle of T0 by n, and outputs the obtained clock signal CLK1 to the counter 132. The frequency division ratio n can be controlled by the control signal RCTRL. n is 1 or a greater integer. The cycle of the clock signal CLK1 is n×T0.

The counter 132 counts detected edges (e.g., rising edges) of the clock signal CLK1, and outputs the obtained count to the logic circuit 133. The logic circuit 133 generates the reset signal RE and the clock pulse signal EN_PULSE in accordance with the count, and outputs the generated signals to the monitor circuits 12_1 to 12_N (see FIG. 1). The control circuit 13 outputs the clock pulse signal (control signal) EN_PULSE, which includes two pulse signals.

FIG. 3 shows the circuit configuration of a monitor circuit 12_i, where i is an integer between 1 and N. All the N monitor circuits 12_1 to 12_N have the same circuit configuration. The monitor circuit 12_i includes a frequency divider (frequency divider circuit) 121, a ring oscillator 122, and a counter 123. The ring oscillator 122 includes a delay gate 124 and a NAND logic gate (hereinafter simply referred to as the NAND) 125.

The frequency divider 121 frequency-divides the clock pulse signal EN_PULSE by two to obtain an enable signal EN, and outputs the obtained enable signal EN to the ring oscillator 122.

The ring oscillator 122 oscillates only during a period T during which the enable signal EN is at a high level (=1), and outputs an oscillation signal ROOUT. More specifically, the enable signal EN is input to one input terminal of the NAND 125 in the ring oscillator 122. An output signal of the NAND 125 is input to the other input terminal of the NAND 125 through the delay gate 124. The ring oscillator 122 then outputs an output signal of the delay gate 124 to the counter 123 as the oscillation signal ROOUT. The delay gate 124 includes, for instance, plural inverters that are serially coupled. Here, the delay gate 124 needs to sufficiently reduce the influence of random variations in the characteristics of the individual inverters upon delay time. Therefore, the number of inverters included in the delay gate 124 is limited so that the delay time remains unaffected.

The counter 123 is initialized to a count of 0 by the reset signal RE before the enable signal EN is set to 1. Subsequently, the counter 123 counts the oscillations (pulses) of the oscillation signal ROOUT during the period T during which the enable signal EN is 1, and outputs a count C_i.

As described earlier, the monitor circuits 12_1 to 12_N shown in FIG. 1 output their respective counts C_i to C_N to the summing circuit 14. The summing circuit 14 then outputs the average count C_{AVE}, which is the average of the counts C_i to C_N. In the present embodiment, the counts C_1 to C_N and the average count C_{AVE} are m-bit binary values, where m is a natural number.

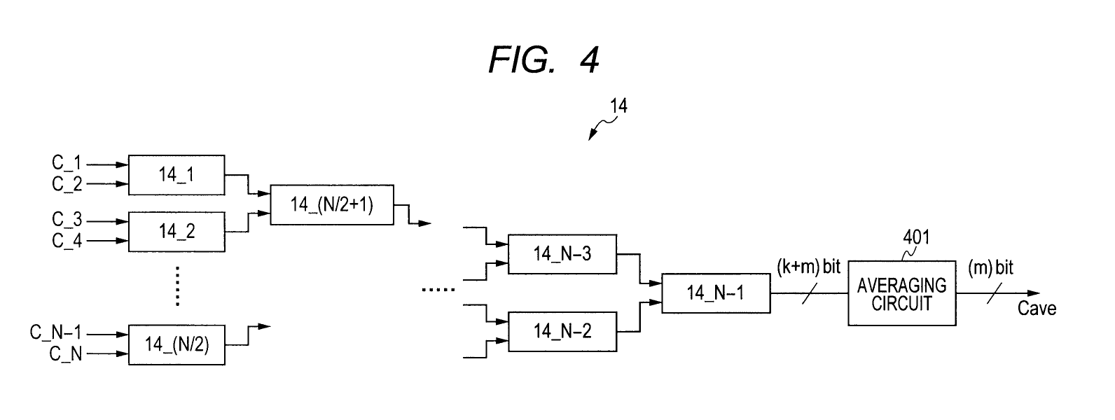

FIG. 4 shows the circuit configuration of the summing circuit 14 on the presumption that the number N of monitor circuits 12_1 to 12_N is the k-th power of 2, where k is 0 or a greater integer. The summing circuit 14 includes adders 14_1 to 14_N−1, which are coupled in a tree configuration, and an averaging circuit 142. More specifically, the adder 14_1 adds the counts C_i, C_2 and outputs the added result. Similarly, the adder 14_(N/2) adds the counts C_N−1, C_N and outputs the added result. At the next stage, the adder 14_(N/2+1) adds the added results produced by the adders 14_1, 14_2 and outputs the result of addition. In this manner, at the final stage, the adder 14_N−1 adds the added results produced by the adders 14_N−3, 14_N−2 and outputs the result of addition.

The averaging circuit 142 receives the result of addition performed by the final adder 14_N−1, and outputs bits starting at the (k+1)th low-order bit position and ending at the (k+m)th lower-order bit position of the received result.

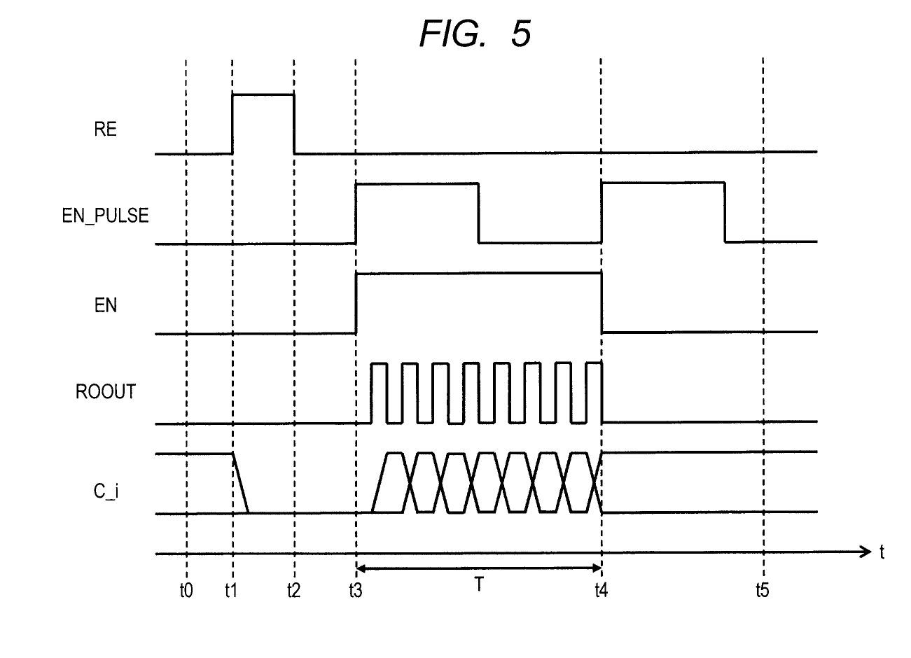

An operation of the semiconductor integrated circuit 11 according to the present embodiment will now be described with reference to a timing diagram of FIG. 5. In an initial state t0 of the monitor circuit 12_i, the reset signal RE and the clock pulse signal EN_PULSE are both 0. Next, when the reset signal RE is 1, the counter 123 is initialized (for a period of time between t1 and t2). Subsequently, the first pulse signal of the clock pulse signal EN_PULSE rises (at time t3). Next, the second pulse signal of the clock pulse signal EN_PULSE rises (at time t4). The frequency divider 121 outputs an enable signal EN of 1 during a period T between t3 and t4, that is, during a period between the instant at which the clock pulse signal EN_PULSE rises and the instant at which the same signal EN_PULSE rises again. The ring oscillator 122 oscillates during the period T and outputs the oscillation signal ROOUT to the counter 123.

The counter 123 counts the oscillations of the oscillation signal ROOUT during the period T, and outputs the resulting count C_i. Here, the count C_i indicates a count T/T_{ROSC} that corresponds to the oscillation cycle T_{ROSC} of the ring oscillator 122 (at time t4).

As mentioned above, the monitor circuits 12_1 to 12_N output their respective counts C_1 to C_N to the summing circuit 14. The summing circuit 14 then averages the counts C_1 to C_N and outputs the resulting average value (C_1+C_2+ . . . +C_N)/N as the average count C_{AVE}.

As described above, the semiconductor integrated circuit according to the present embodiment can detect an average value representing the variations in the characteristics in a chip by using the monitor circuits disposed at plural locations within the chip. Here, the semiconductor integrated circuit according to the present embodiment controls the oscillation time of the ring oscillator included in each monitor circuit by using the clock pulse signal EN_PULSE alone. Therefore, the semiconductor integrated circuit according to the present embodiment differs from those based on the conventional technology in that the oscillation time of the ring oscillator does not vary due to a significant skew between two control signals (e.g., the reference clock and measurement start signal based on the conventional technology). In other words, the semiconductor integrated circuit according to the present embodiment ensures that the ring oscillators in the monitor circuits precisely agree in oscillation time. Consequently, the semiconductor integrated circuit according to the present embodiment can monitor the performance of the chip with high accuracy.

Further, the semiconductor integrated circuit according to the present embodiment can control the frequency division ratio n of the cycle T0 of the clock signal CLK0 by using the frequency divider 131 included in the control circuit 13. Therefore, the oscillation time of the ring oscillator 122 included in each monitor circuit can always be set within a desired range without regard to the cycle T0 of the clock signal CLK0. Consequently, the semiconductor integrated circuit according to the present embodiment can evaluate the performance of chips having different operating frequencies by using the monitor circuits having the same circuit configuration.

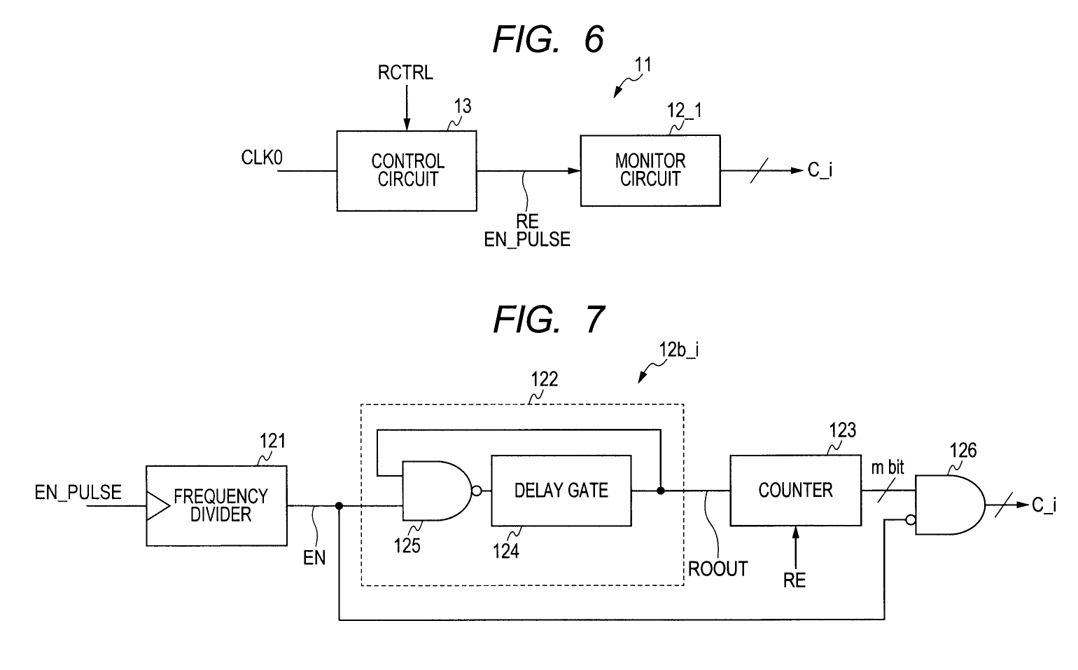

In the present embodiment, it is assumed that N is the k-th power of 2. However, N need not always be the k-th power of 2. Alternatively, N may be any natural number. If N is a natural number other than the k-th power of 2, a complex circuit configuration results because the summing circuit 14 needs to additionally include a divider having a divisor of N. However, the versatility of the monitor circuits will be increased. If N is equal to 1, the summing circuit 14 need not be used; therefore, the circuit configuration need not include the summing circuit 14 as indicated in FIG. 6. In this instance, the monitor circuit 12_1 outputs the count C_1 as a final monitor output value (average count C_{AVE}).

In the present embodiment, it is assumed that the monitor circuit 12_i shown in FIG. 3 is used. However, the present invention is not limited to the use of the monitor circuit 12_i. For example, the present embodiment can also be applied to a circuit configuration that includes a monitor circuit 12b_i (i is an integer between 1 and N) shown in FIG. 7. The circuit shown in FIG. 7 differs from the circuit shown in FIG. 3 in that the former includes a gating circuit 126 having m AND logic gates (hereinafter simply referred to as the ANDS). An inverted version of the enable signal EN is input to one terminal of each of the m ANDS. An output signal of a bit line corresponding to the counter 123 is input to the other terminal of each of the m ANDS. The output signal of the counter 123 is m bits wide.

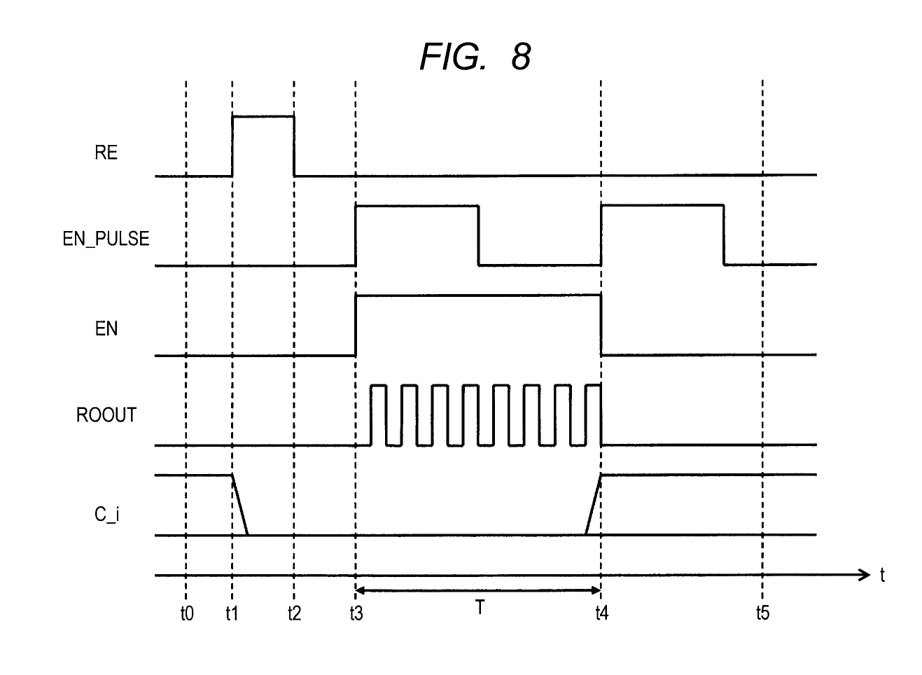

While the enable signal EN is 1, the monitor circuit 12b_i does not output the count of the counter 123 as the count C_i, but outputs a value of 0. When the enable signal EN changes from 1 to 0, the monitor circuit 12b_i outputs a final count of the counter 123 as the count C_i. This circuit configuration ensures that the count C_i reached during the oscillation of the ring oscillator 122 (during the period T) is not output, as indicated in FIG. 8. Consequently, the number of switchings concerning the wiring between the monitor circuit 12b_i and the summing circuit 14 can be decreased to reduce noise and power consumption.

In the present embodiment, it is assumed that the frequency divider 121 frequency-divides the clock pulse signal EN_PULSE by two to generate the enable signal EN. However, the present invention is not limited to the use of such an enable signal generation method. The present invention can also be applied to a circuit configuration in which all the pulses R of the clock pulse signal EN_PULSE are input to generate the enable signal EN while the frequency division ratio of the frequency divider 121 is R (R is a natural number).

In the present embodiment, it is assumed that the control circuit 13 outputs the same clock pulse signal EN_PULSE to the monitor circuits 12_1 to 12_N. However, the present invention is not limited to the use of such a circuit configuration. The present invention can also be applied to a circuit configuration in which the control circuit 13 outputs different clock pulse signals EN_PULSE_i (i is an integer between 1 and N) to the monitor circuits 12_1 to 12_N. In this instance, the average count CAVE of a longer sampling period can be detected by generating the clock pulse signals EN_PULSE_i in such a manner that the ring oscillators 122 included in the monitor circuits 12_1 to 12_N do not oscillate at the same time. This makes it possible to detect the characteristics of a chip that prevail during a longer sampling period.

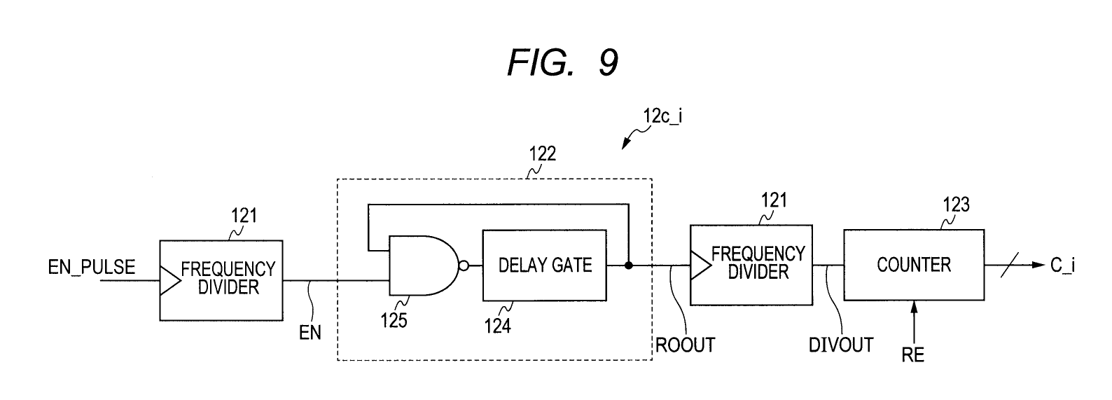

In the present embodiment, it is assumed that the monitor circuit 12_i shown in FIG. 3 is used. However, the present invention is not limited to the use of such a circuit configuration. The present invention can also be applied to a circuit configuration that uses a monitor circuit 12c_i is an integer between 1 and N) shown in FIG. 9. The circuit shown in FIG. 9 differs from the circuit shown in FIG. 3 in that a frequency divider 127 is added between the ring oscillator 122 and the counter 123. The frequency divider 127 frequency-divides the oscillation signal ROOUT by a frequency division ratio of a (a is a natural number) and outputs the resulting frequency-divided signal DIVOUT to the counter 123.

The above-described circuit configuration makes it possible to decrease the frequency of the frequency-divided signal DIVOUT to a desired value even when the oscillation frequency of the ring oscillator 122 is high. This permits the counter 123 to lower the upper limit of its count. Thus, the bit width of the output signal can be decreased. It means that the number of digits required for the counter 123 can be decreased. Further, even when the cycle T0 of the clock signal CLK0 is excessively long, the bit width of the output signal of the counter 123 can be decreased by increasing the frequency division ratio a. In other words, the number of digits required for the counter 123 can be decreased.

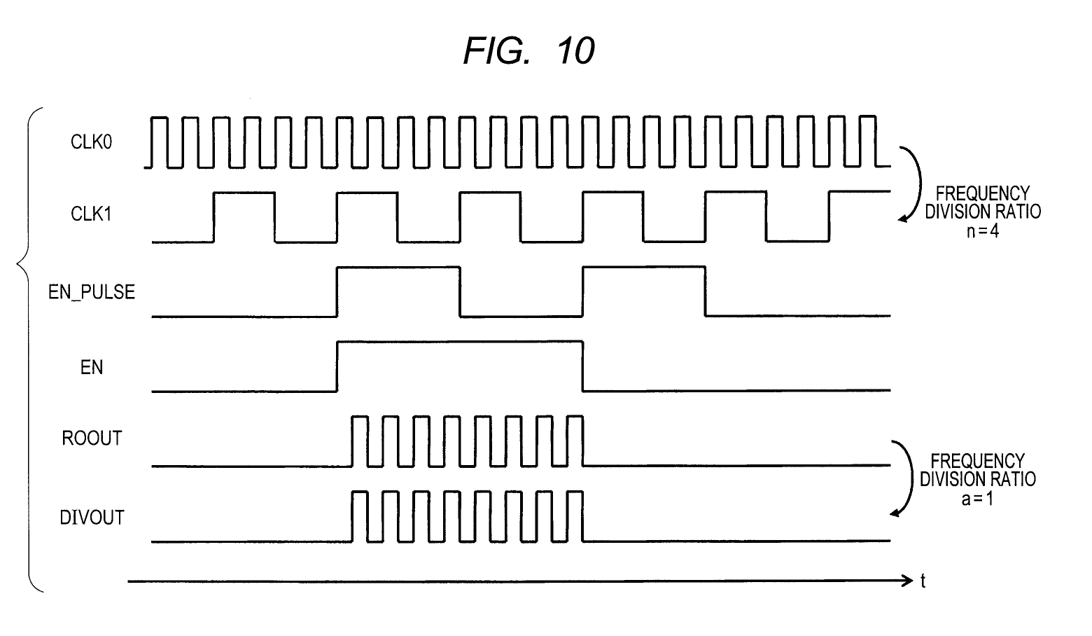

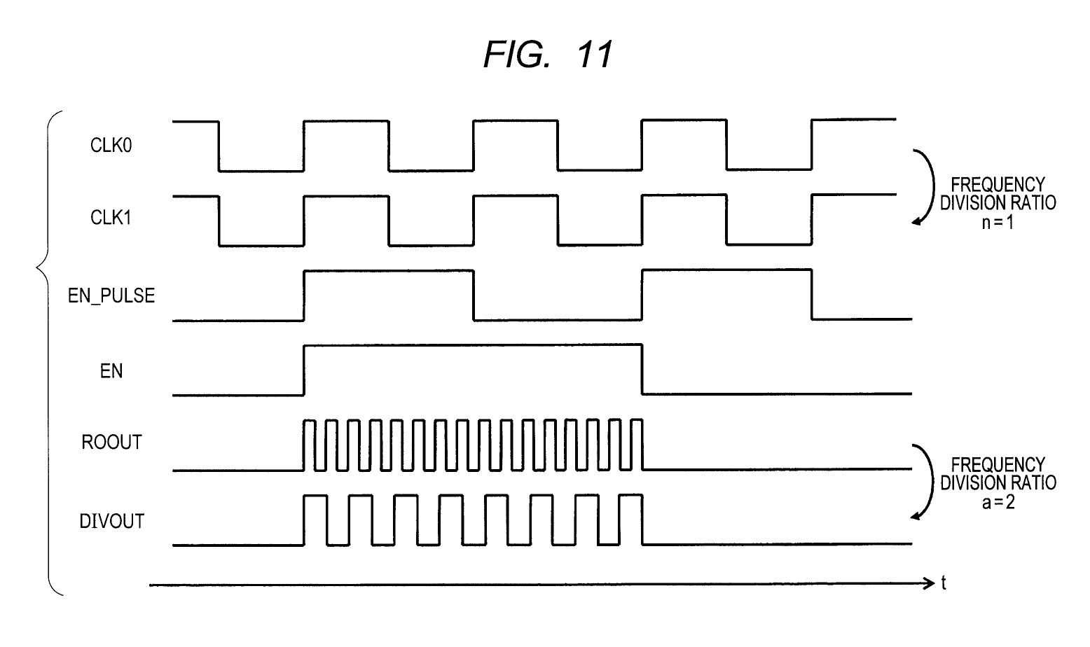

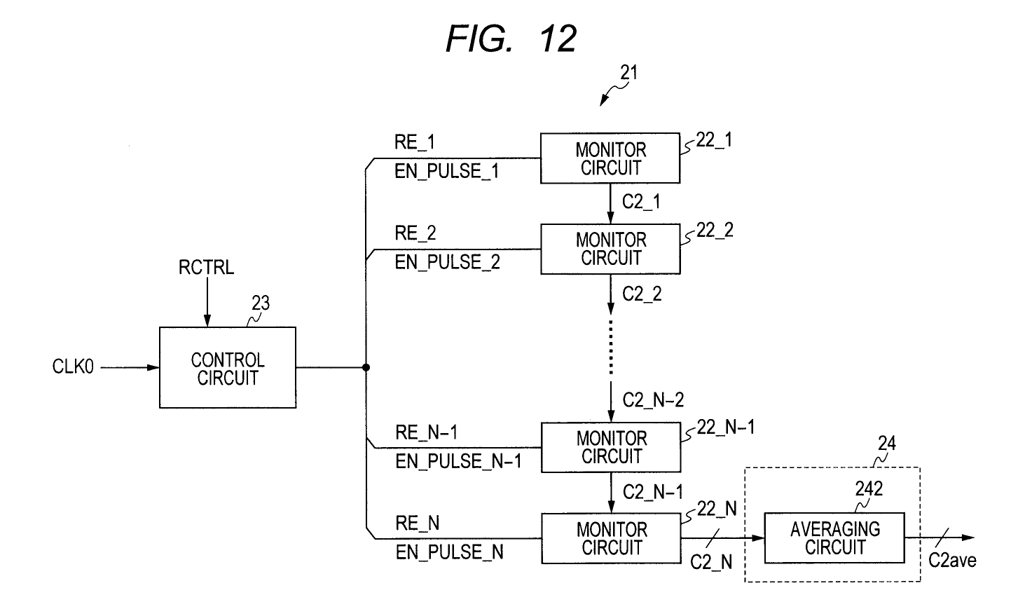

When, for instance, the cycle T0 of the clock signal CLK0 is short, the frequency division ratio n of the frequency divider 131 is increased as shown in FIG. 10 with the frequency division ratio a of the frequency divider 127 decreased. When, on the other hand, the cycle T0 of the clock signal CLK0 is long, the frequency division ratio n of the frequency divider 131 is decreased as shown in FIG. 11 with the frequency division ratio a of the frequency divider 127 increased. This makes it possible to decrease the bit width of the output signal of the counter 123. At the same time, the count C_i of the monitor circuit 12_i can be confined within a desired range without regard to the cycle T0 of the clock signal CLK0. In other words, the number of digits required for the counter 123 can be maintained within an equivalent range without regard to the cycle T0 of the clock signal CLK0. Consequently, the performance of chips having different operating frequencies can be evaluated by using the monitor circuits having the same circuit configuration.

### Second Embodiment

FIG. 12 is a block diagram illustrating a semiconductor integrated circuit 21 according to a second embodiment of the present invention. The circuit shown in FIG. 12 includes monitor circuits 22_1 to 22_N, a control circuit 23, and a summing circuit 24. The summing circuit 24 includes an averaging circuit 242. N is equal to the k-th power of 2 (k is 0 or a greater integer).

The control circuit 23 inputs the clock signal CLK0 and the control signal RCTRL, and outputs reset signals RE_1 to RE_N and clock pulse signals EN_PULSE_1 to EN_PULSE_N to the associated monitor circuits 22_1 to 22_N. The monitor circuit 22_1 outputs a count C2_1 to the monitor circuit 22_2. The monitor circuit 22_2 outputs a count C2_2 to the monitor circuit 22_3. In this manner, the monitor circuits 22_1 to 22_N−1 output counts C2_1 to C2_N−1 to the succeeding monitor circuits 22_2 to 22_N, respectively. The monitor circuit 22_N outputs a count C2_N to the averaging circuit 242. The averaging circuit 242 outputs an average count C2_{AVE}, which is the average value of the counts C2_1 to C2_N. It should be noted that the monitor circuits 22_1 to 22_N are adapted to detect the characteristics of a chip that are dependent on process level, temperature, and supply voltage.

The control circuit 23 will not be described in detail because it has the same circuit configuration as that of the control circuit 13 except that the former outputs different reset signals RE_1 to RE_N and clock pulse signals EN_PULSE_1 to EN_PULSE_N to the monitor circuits 22_1 to 22_N. The control circuit 23 outputs the clock pulse signals EN_PULSE_1 to EN_PULSE_N, which each include two pulse signals.

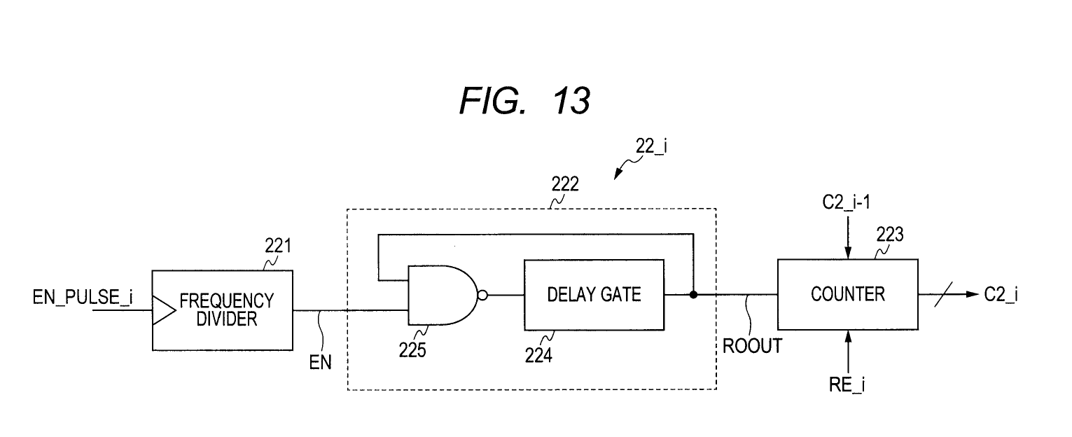

FIG. 13 shows the circuit configuration of a monitor circuit 22_i, where i is an integer between 1 and N. All the N monitor circuits 221 to 22_N have the same circuit configuration. The monitor circuit 22_i includes a frequency divider 221, a ring oscillator 222, and a counter 223. The ring oscillator 222 includes a delay gate 224 and a NAND 225.

The frequency divider 221 frequency-divides the clock pulse signal EN_PULSE_i by two, and outputs the resulting frequency-divided signal to the ring oscillator 222 as the enable signal EN.

The ring oscillator 222 oscillates only during the period T during which the enable signal EN is at a high level (=1), and outputs the oscillation signal ROOUT. The ring oscillator 222 will not be described in detail here because it has the same circuit configuration as that of the ring oscillator 122 according to the first embodiment. The NAND 225 corresponds to the NAND 125, and the delay gate 224 corresponds to the delay gate 124.

The counter 223 is set to a count C2_i−1 of the preceding monitor circuit 22_i−1 by a reset signal RE_i before the enable signal EN is set to 1. In the case of the monitor circuit 22_1 (when i=1), the counter 223 is initialized to a count of 0 by a reset signal RE_1 before the enable signal EN is set to 1. Subsequently, the counter 223 counts the oscillations (pulses) of the oscillation signal ROOUT during the period T during which the enable signal EN is 1, and outputs the sum of the resulting count and a count C2_i as the count C2_i.

The monitor circuit 22_N outputs the sum of the counts reached by the monitor circuits 22_1 to 22_N to the averaging circuit 242 as the count C2_N. The averaging circuit 242 divides the count C2_N by N and outputs the resulting value as the average count C2_{AVE}. The counts C2_N, C2_{AVE} are both binary values. When the number N of monitor circuits is equal to the k-th power of 2, the averaging circuit 242 functions as a shifter that shifts the count C2_N toward least significant bit positions by k bits and outputs the (k+1)th least significant bit and higher-order bits.

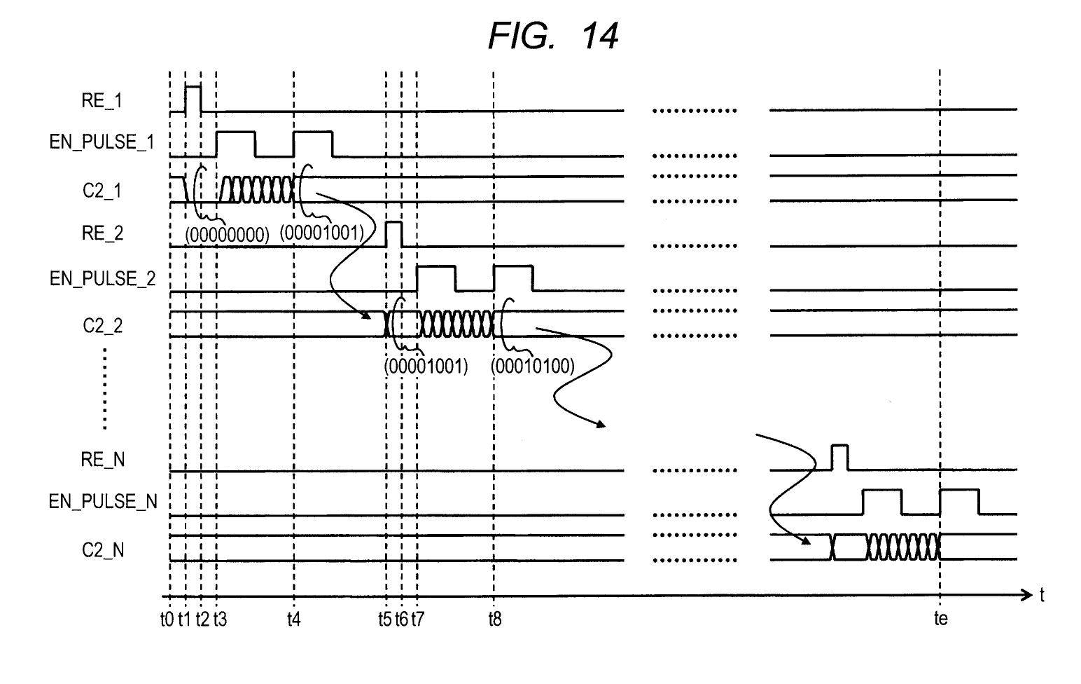

An operation performed by the semiconductor integrated circuit 21 according to the present embodiment will now be described with reference to a timing diagram of FIG. 14. In the initial state t0, the reset signal RE and the clock pulse signal EN_PULSE_i are both 0.

First of all, an operation of the monitor circuit 22_1 will be described with reference to the timing diagram of FIG. 14. When the reset signal RE_1 is 1, the counter 223 is initialized (for a period of time between t1 and t2). Subsequently, the first pulse signal of the clock pulse signal EN_PULSE_1 rises (at time t3). Next, the second pulse signal of the clock pulse signal EN_PULSE_1 rises (at time t4). The frequency divider 221 outputs an enable signal EN of 1 during a period T between t3 and t4, that is, during a period between the instant at which the clock pulse signal EN_PULSE_1 rises and the instant at which the same signal EN_PULSE_1 rises again. The ring oscillator 222 oscillates during the period T and outputs the oscillation signal ROOUT to the counter 223. The counter 223 counts the oscillations of the oscillation signal ROOUT during the period T, and outputs the resulting count C2_1. Here, the count C2_1 indicates a count T/T_{ROSC1} that corresponds to the oscillation cycle T_{ROSC1} of the ring oscillator 222 (at time t4). The following description illustrates a case where the count C2_1 is 00001001 in binary notation.

An operation of the monitor circuit 22_2 will now be described with reference to the timing diagram of FIG. 14. When a reset signal RE_2 is 1, the counter 223 is set to the count C2_1 (=T/T_{ROSC1}) of the monitor circuit 22_1 (for a period of time between 5t and t6). Subsequently, the first pulse signal of the clock pulse signal EN_PULSE_2 rises (at time t7). At this time, the count C2_2 is equal to the count C2_1 (00001001). Next, the second pulse signal of the clock pulse signal EN_PULSE_2 rises (at time t8). The frequency divider 221 outputs an enable signal EN of 1 during a period T between t7 and t8, that is, during a period between the instant at which the clock pulse signal EN_PULSE_2 rises and the instant at which the same signal EN_PULSE_2 rises again. The ring oscillator 222 oscillates during the period T and outputs the oscillation signal ROOUT to the counter 223. The counter 223 counts the oscillations of the oscillation signal ROOUT during the period T, and outputs the sum of the resulting count and a count C2_1 as the count C2_2. Here, the count C2_2 indicates the sum of a count T/T_{ROSC2} corresponding to the oscillation cycle T_{ROSC2} of the ring oscillator 222 and the count C2_1 (at time t8). The following description illustrates a case where T/T_{ROSC2} is 00001011. In this case, the count C22 reached at time t8 indicates 00010100 because it is T/T_{ROSC1}+T/T_{Rosc2}.

Subsequently, the same operation is performed in the monitor circuit 22_i (i=3, 4, N) as in the monitor circuit 22_2. When the reset signal RE_i is 1, the counter 223 of the monitor circuit 22_i is set to the count C2_i−1. The count C2_1 reached upon completion of counting by the monitor circuit 22_i is expressed by Equation (1) below:

$$C 2 \_i = {\sum }_{k = 1}^{i} \frac{T}{{T}_{ROSCk}} \qquad ( 1 )$$

Upon completion of counting (at time te), the monitor circuit 22_N outputs the count C2_N to the averaging circuit 242. The averaging circuit 242 divides the count C2_N by N and outputs the resulting value C2_N/N as the average count C2_{AVE}. In other words, the averaging circuit 242 divides the count C2_N by N and outputs the resulting value C2_N/N as a final monitor output value.

As described above, the semiconductor integrated circuit according to the present embodiment can detect an average value representing the variations in the characteristics in a chip by using the monitor circuits disposed at plural locations within the chip. Here, the semiconductor integrated circuit according to the present embodiment controls the oscillation time of the ring oscillator included in each monitor circuit by using the associated clock pulse signal EN_PULSE alone. Therefore, like the semiconductor integrated circuit according to the first embodiment, the semiconductor integrated circuit according to the present embodiment ensures that the ring oscillators included in the monitor circuits precisely agree in oscillation time. Consequently, the semiconductor integrated circuit according to the present embodiment can monitor the performance of the chip with high accuracy. Further, in the semiconductor integrated circuit according to the present embodiment, all the outputs of the monitor circuits need not be coupled to the summing circuit 24. In other words, the semiconductor integrated circuit according to the present embodiment is configured by merely coupling the output of each monitor circuit to a neighboring monitor circuit. This makes it possible to reduce the overall wiring length.

In the present embodiment, the summing circuit 24 divides the count C2_N by N and outputs the resulting value C2_N/N as the monitor output value. However, the present invention is not limited to the use of such a circuit configuration. The present invention can also be applied to a circuit configuration in which the count C2_N is output as the monitor output value instead of the count C2_N/N. If such an alternative circuit configuration is employed, the averaging circuit 242 is not required.

### Third Embodiment

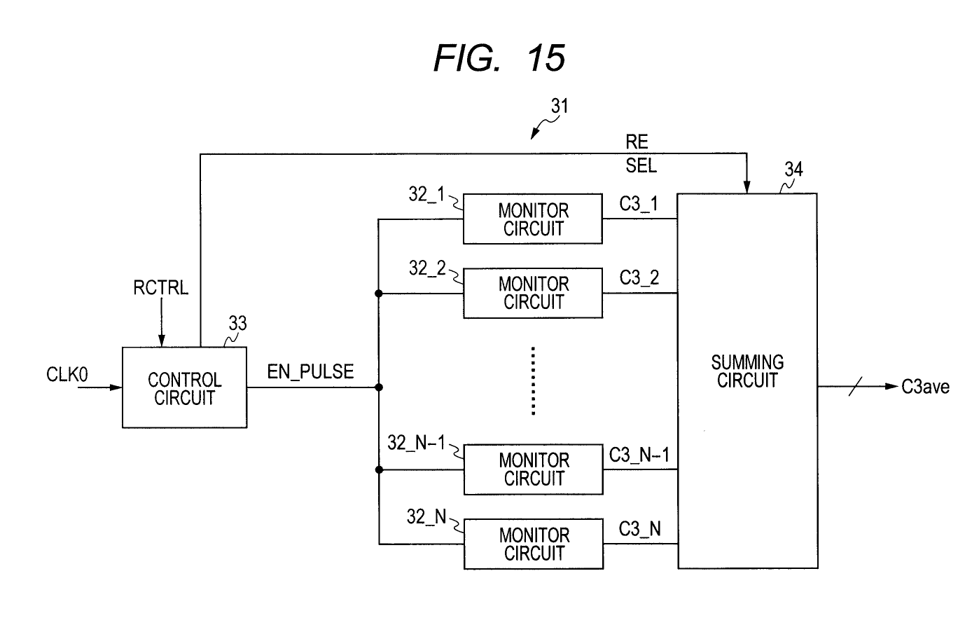

FIG. 15 is a block diagram illustrating a semiconductor integrated circuit 31 according to a third embodiment of the present invention. The circuit shown in FIG. 15 includes monitor circuits 32_1 to 32_N, a control circuit 33, and a summing circuit 34. N is equal to the k-th power of 2 (k is 0 or a greater integer).

The control circuit 33 inputs the clock signal CLK0 and the control signal RCTRL, outputs the reset signal RE and an s-bit select signal SEL to the summing circuit 34, and outputs the clock pulse signal EN_PULSE to the monitor circuits 32_1 to 32_N. It should be noted that 2̂(s−1)<N<2̂s. The monitor circuits 32_1 to 32_N output their respective oscillation signals C3_1 to C3_N to the summing circuit 34. The summing circuit 34 outputs an average count C3_{AVE} in accordance with the oscillation signals C3_1 to C3_N. The monitor circuits 32_1 to 32_N are adapted to detect the characteristics of a chip that are dependent on process level, temperature, and supply voltage.

The control circuit 33 will not be described in detail because it has the same circuit configuration as that of the control circuit 13 except that the former outputs the s-bit select signal SEL. Each time the value of the select signal SEL changes, the control circuit 33 outputs the clock pulse signals EN_PULSE, which includes two pulse signals.

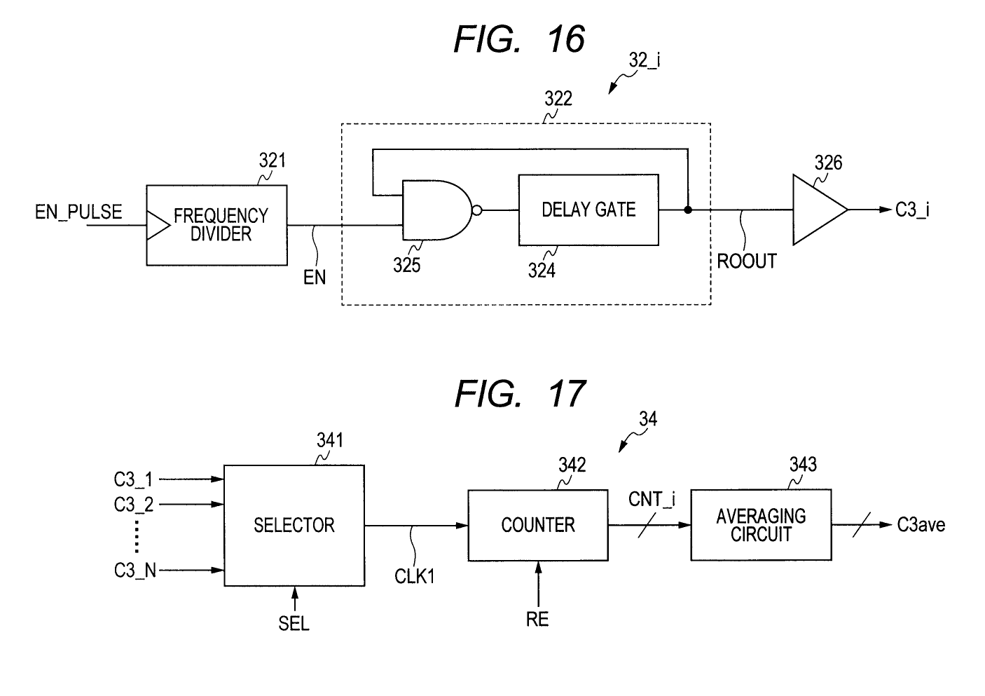

FIG. 16 shows the circuit configuration of a monitor circuit 32_i, where i is an integer between 1 and N. All the N monitor circuits 321 to 32_N have the same circuit configuration. The monitor circuit 32_i includes a frequency divider 321, a ring oscillator 322, and an output buffer 326. The ring oscillator 322 includes a delay gate 324 and a NAND 325.

The frequency divider 321 frequency-divides the clock pulse signal EN_PULSE by two, and outputs the resulting frequency-divided signal to the ring oscillator 322 as the enable signal EN.

The ring oscillator 322 oscillates only during the period T during which the enable signal EN is at a high level (=1), and outputs the oscillation signal ROOUT. The ring oscillator 322 will not be described in detail here because it has the same circuit configuration as that of the ring oscillator 122 according to the first embodiment. The NAND 325 corresponds to the NAND 125, and the delay gate 324 corresponds to the delay gate 124. The output buffer 326 drives the oscillation signal ROOUT and outputs it as an oscillation signal C3_i.

FIG. 17 shows the circuit configuration of the summing circuit 34. The summing circuit 34 includes a selector 341, a counter 342, and an averaging circuit 343. The selector 341 sequentially selects the oscillation signals C3_1 to C3_N in accordance with the select signal SEL and outputs the selected oscillation signals to the counter 342. The counter 342 counts the oscillations (pulses) of the oscillation signal C3_i selected by the selector 341, and outputs a count CNT_i. Subsequently, the selector 341 switches to the next oscillation signal C3_i and outputs it to the counter 342. In this manner, the counter 342 counts the oscillations of all oscillation signals C3_1 to C3_N.

The averaging circuit 343 divides the total number of oscillations of the oscillation signals C3_1 to C3_N by N, and outputs the resulting value as the average count C3_{AVE}. In other words, the averaging circuit 343 divides a count CNT_N by N and outputs the resulting value as the average count C3_{AVE}. The values CNT_i and C3_{AVE} are in binary notation. When the number N of monitor circuits is equal to the k-th power of 2, the averaging circuit 343 functions as a shifter that shifts the count CNT_i toward least significant bit positions by k bits and outputs the (k+1)th least significant bit and higher-order bits.

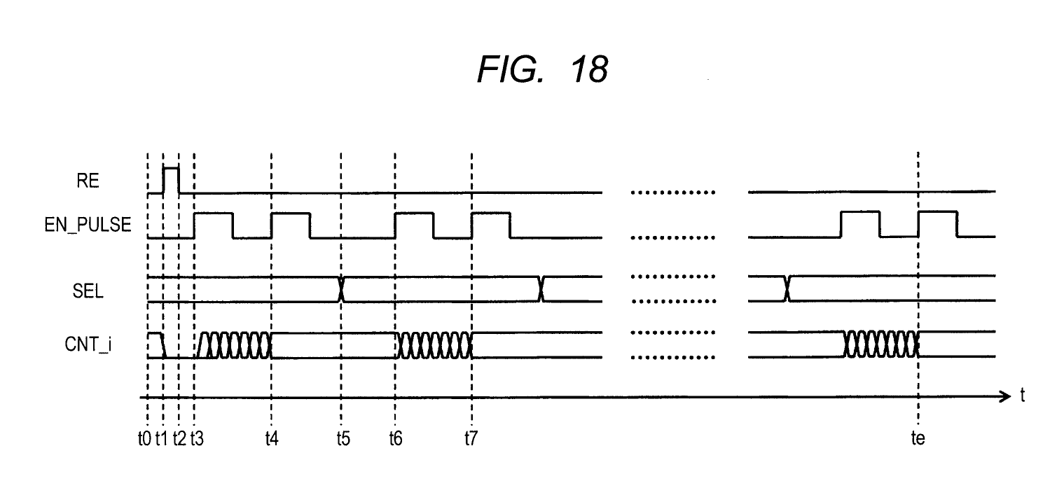

An operation performed by the semiconductor integrated circuit 31 according to the present embodiment will now be described with reference to a timing diagram of FIG. 18. In the initial state t0, the reset signal RE and the clock pulse signal EN_PULSE are both 0. Further, the selector 341 is in a state where the oscillation signal C3_1 is selected by the select signal SEL.

In the monitor circuit 32_1, the counter 342 is initialized (for a period of time between t1 and t2) when the reset signal RE is 1. Subsequently, the first pulse signal of the clock pulse signal EN_PULSE rises (at time t3). Next, the second pulse signal of the clock pulse signal EN_PULSE rises (at time t4). In the monitor circuit 32_1, the frequency divider 321 outputs an enable signal EN of 1 during a period T between t3 and t4, that is, during a period between the instant at which the clock pulse signal EN_PULSE rises and the instant at which the same signal EN_PULSE rises again. The ring oscillator 322 oscillates during the period T and outputs the oscillation signal ROOUT to the output buffer 326. The output buffer 326 drives the oscillation signal ROOUT and outputs it as the oscillation signal C3_1. The counter 342 included in the summing circuit 34 counts the oscillations of the oscillation signal C3_1 during the period T, and outputs the resulting count CNT_1. Here, the count CNT_1 indicates a count T/T_{ROSC1} that corresponds to the oscillation cycle T_{ROSC1} of the ring oscillator 322 included in the monitor circuit 32_1 (at time t4).

Next, the value of the select signal SEL changes (at time t5). The selector 341 then selects an oscillation signal C3_2 and outputs it to the counter 342. After the select signal SEL is changed, the first pulse signal of the clock pulse signal EN_PULSE rises (at time t6). Subsequently, the second pulse signal of the clock pulse signal EN_PULSE rises (at time t7). The monitor circuit 32_2 outputs the oscillation signal C3_2 for a period T between t6 and t7. The counter 342 included in the summing circuit 34 counts the oscillations of the oscillation signal C3_2 during the period T, and outputs the sum of the resulting count and the count CNT_1 as a count CNT_2. In this manner, the counter 342 counts the oscillations of all oscillation signals C3_1 to C3_N and outputs the resulting count as the count CNT_N (at time te).

The count CNT_i reached when the counter 342 completes the counting of oscillation signals of up to C3_i is expressed by Equation (2) below:

$$CNT\_i = {\sum }_{k = 1}^{i} \frac{T}{{T}_{ROSCk}} \qquad ( 2 )$$

The averaging circuit 343 divides the total count CNT_N of the oscillations of the oscillation signals C3_1 to C3_N by N and outputs the resulting value CNT_N/N as the average count C3_{AVE}. In other words, the averaging circuit 343 divides the count CNT_N by N and outputs the resulting value CNT_N/N as a final monitor output value.

As described above, the semiconductor integrated circuit according to the present embodiment can detect an average value representing the variations in the characteristics in a chip by using the monitor circuits disposed at plural locations within the chip. Here, the semiconductor integrated circuit according to the present embodiment controls the oscillation time of the ring oscillator included in each monitor circuit by using the clock pulse signal EN_PULSE alone. Therefore, like the semiconductor integrated circuit according to the first embodiment, the semiconductor integrated circuit according to the present embodiment ensures that the ring oscillators included in the monitor circuits precisely agree in oscillation time. Consequently, the semiconductor integrated circuit according to the present embodiment can monitor the performance of the chip with high accuracy. Further, the area occupied by the semiconductor integrated circuit according to the present embodiment can be decreased because each monitor circuit does not need to include a counter.

In the present embodiment, the summing circuit 34 divides the count CNT_N by N and outputs the resulting value CNT_N/N as the monitor output value. However, the present invention is not limited to the use of such a circuit configuration. The present invention can also be applied to a circuit configuration in which the count CNT_N is output as the monitor output value instead of the count CNT_N/N. If such an alternative circuit configuration is employed, the averaging circuit 343 is not required.

### Fourth Embodiment

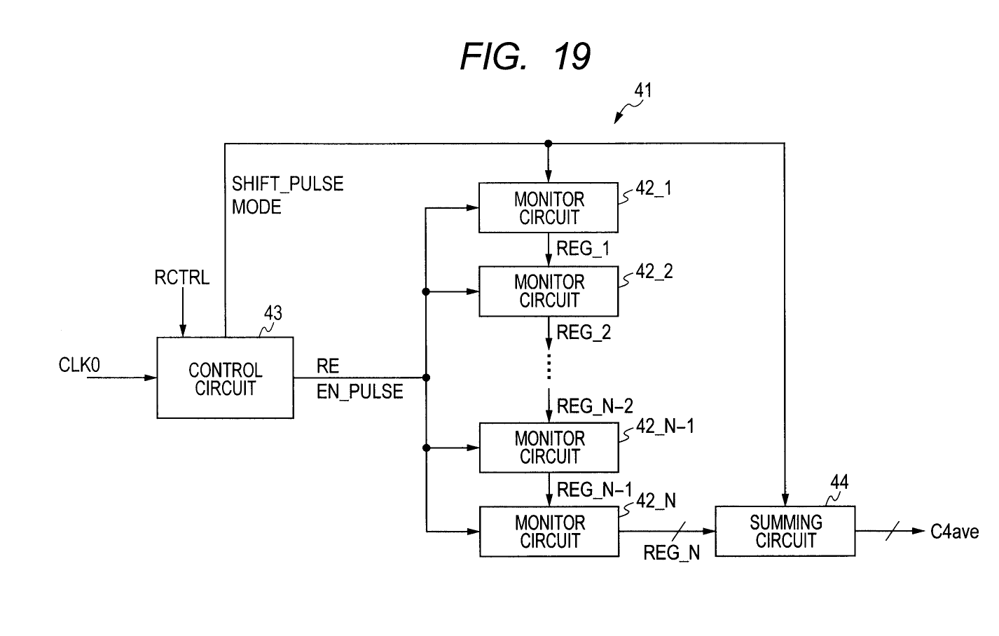

FIG. 19 is a block diagram illustrating a semiconductor integrated circuit 41 according to a fourth embodiment of the present invention. The circuit shown in FIG. 19 includes monitor circuits 42_1 to 42_N, a control circuit 43, and a summing circuit 44. N is equal to the k-th power of 2 (k is 0 or a greater integer).

The control circuit 43 inputs the clock signal CLK0 and the control signal RCTRL, and outputs a shift pulse signal SHIFT_PULSE and a control signal MODE to the monitor circuits 42_1 to 42_N and the summing circuit 44. Further, the control circuit 43 outputs the reset signal RE and the clock pulse signal EN_PULSE to the monitor circuits 42_1 to 42_N. The monitor circuit 42_1 outputs a register value REG_1 to the monitor circuit 42_2. The monitor circuit 42_2 outputs a register value REG_2 to the monitor circuit 42_3. In this manner, the monitor circuits 42_1 to 42_N−1 output register values REG_1 to REG_N−1 to the succeeding monitor circuits 42_2 to 42_N. The monitor circuit 42_N outputs a register value REG_N to the summing circuit 44. The summing circuit 44 outputs an average count C4_{AVE} in accordance with the register values REG_1 to REG_N. The monitor circuits 42_1 to 42_N are adapted to detect the characteristics of a chip that are dependent on process level, temperature, and supply voltage.

The control circuit 43 will not be described in detail because it has the same circuit configuration as that of the control circuit 13 except that the former outputs the shift pulse signal SHIFT_PULSE and the control signal MODE. It should also be noted that the control circuit 43 outputs the clock pulse signals EN_PULSE, which includes two pulse signals.

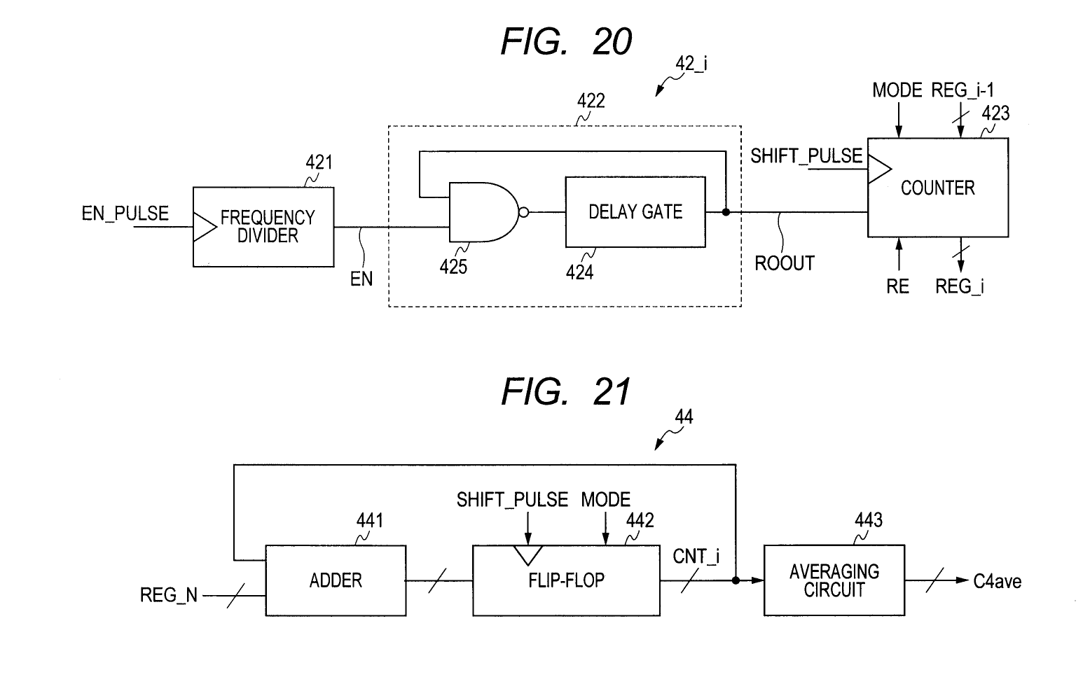

FIG. 20 shows the circuit configuration of a monitor circuit 42_i, where i is an integer between 1 and N. All the N monitor circuits 42_1 to 42_N have the same circuit configuration. The monitor circuit 42_i includes a frequency divider 441, a ring oscillator 422, and a counter 423. The ring oscillator 422 includes a delay gate 424 and a NAND 425.

The frequency divider 421 frequency-divides the clock pulse signal EN_PULSE by two, and outputs the resulting frequency-divided signal to the ring oscillator 422 as the enable signal EN.

The ring oscillator 422 oscillates only during the period T during which the enable signal EN is at a high level (=1), and outputs the oscillation signal ROOUT. The ring oscillator 422 will not be described in detail here because it has the same circuit configuration as that of the ring oscillator 122 according to the first embodiment. The NAND 425 corresponds to the NAND 125, and the delay gate 424 corresponds to the delay gate 124.

The counter 423 is a synchronous counter that includes plural flip-flops (e.g., m flip-flops) (not shown), the number of which corresponds to the bit width of an output signal (e.g., m bits). First of all, the counter 423 is initialized to a count of 0 by the reset signal RE before the enable signal EN is set to 1. Subsequently, when the control signal MODE is 0 (in a count mode), the counter 423 counts the oscillations of the oscillation signal ROOUT. More specifically, the counter 423 counts the oscillations (pulses) of the oscillation signal R_{OUT} during the period T during which the enable signal EN is 1, and stores the resulting count C4_i in the internal flip-flops. A value stored in the flip-flops is referred to as a register value REG_i. In the count mode, therefore, the register value REG_i indicates the count C4_i. When, on the other hand, the control signal MODE is 1 (in a shift mode), each flip-flop fetches a value stored in a flip-flop corresponding the preceding monitor circuit 42_i−1 in synchronism with the shift pulse signal SHIFT_PULSE. More specifically, the j-th flip-flop (j is an integer between 1 and m) fetches a value stored in the j-th flip-flop in the preceding monitor circuit 42_i−1 in synchronism with the shift pulse signal SHIFT_PULSE.

In other words, when the control signal MODE is 1, the monitor circuit 42_i fetches a register value REG_i−1 output from the preceding monitor circuit 42_i−1 in synchronism with the shift pulse signal SHIFT_PULSE, and outputs the fetched register value to the monitor circuit 42_i+1 as the register value REG_i. When the control signal MODE is 1, the monitor circuit 42_N outputs the register value REG_N to the summing circuit 44. As described above, the monitor circuits 42_1 to 42_N switch between the count mode and the shift mode in accordance with the control signal MODE.

FIG. 21 shows the circuit configuration of the summing circuit 44. The summing circuit 44 includes an adder 441, a flip-flop 442, and an averaging circuit 443. The adder 441 adds an output signal of the flip-flop 442 to the register value REG_N output from the monitor circuit 42_N, and outputs the resulting value to the flip-flop 442. When the control signal MODE is 0, the flip-flop 442 outputs a count CNT of 0. When, on the other hand, the control signal MODE is 1, the flip-flop 442 fetches the output signal of the adder 441 in synchronism with the shift pulse signal SHIFT_PULSE, and outputs the fetched signal as the count CNT_i.

The averaging circuit 443 divides the count CNT_N by N, and outputs the resulting value as the average count C4_{AVE}. When the number N of monitor circuits is equal to the k-th power of 2, the averaging circuit 443 functions as a shifter that shifts the count CNT_N toward least significant bit positions by k bits and outputs the (k+1)th least significant bit and higher-order bits.

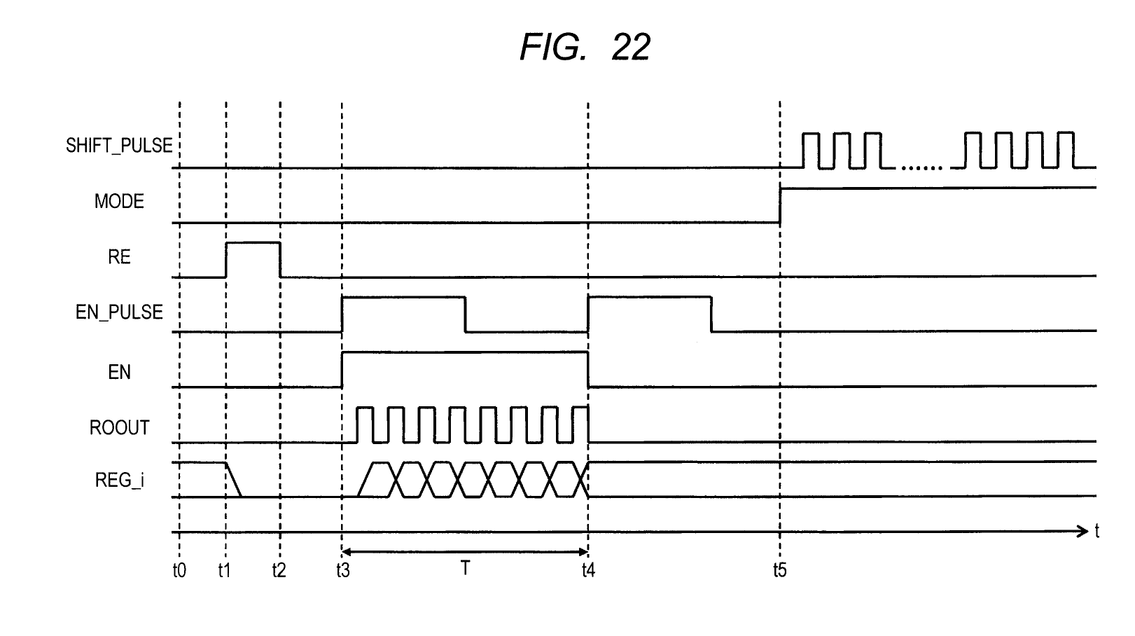

An operation performed by the semiconductor integrated circuit 41 according to the present embodiment will now be described with reference to a timing diagram of FIG. 22. In the initial state t0, the reset signal RE, the clock pulse signal EN_PULSE, and the control signal MODE are all 0.

In the monitor circuit 42_i, the counter 423 is initialized (for a period of time between t1 and t2) when the reset signal RE is 1. Subsequently, the first pulse signal of the clock pulse signal EN_PULSE rises (at time t3). Next, the second pulse signal of the clock pulse signal EN_PULSE rises (at time t4). In the monitor circuit 42_i, the frequency divider 421 outputs an enable signal EN of 1 during a period T between t3 and t4, that is, during a period between the instant at which the clock pulse signal EN_PULSE rises and the instant at which the same signal EN_PULSE rises again. The ring oscillator 422 oscillates during the period T and outputs the oscillation signal ROOUT to the counter 423. The counter 423 counts the oscillations of the oscillation signal ROOUT during the period T, and stores the resulting count C4. Here, the count C4_i indicates a value T/T_{ROSC1} that corresponds to the oscillation cycle T_{ROSC1} of the ring oscillator 422 (at time t4).

Next, the value of the control signal MODE changes from 0 to 1 (at time t5). It means that the selected mode changes from the count mode to the shift mode. The counters 423 of the monitor circuits 42_1 to 42_N are then serially coupled to form an N-bit shift register. When the register value REG_i is m bits wide, the flip-flops that are included in the monitor circuits 42_1 to 42_N and provided for the associated bits are serially coupled to form the N-bit shift register.

At time t5 and later, the monitor circuit 42_i fetches the register value REG_i−1 output from the preceding monitor circuit 42_i−1 in synchronism with the shift pulse signal SHIFT_PULSE, and outputs the fetched register value to the monitor circuit 42_i+1 as the register value REG_i. It should be noted that the monitor circuit 42_N outputs the register value REG_N to the summing circuit 44.

The adder 441 included in the summing circuit 44 adds the output signal of the flip-flop 442 to the register value REG_N output from the monitor circuit 42_N, and outputs the resulting value to the flip-flop 442. The flip-flop 442 fetches the signal output from the adder 441 in synchronism with the shift pulse signal SHIFT_PULSE, and outputs the fetched signal as the count CNT_N. More specifically, the flip-flop 442 outputs the total count CNT_N of the monitor circuits 42_1 to 42_N after the shift pulse signal SHIFT_PULSE rises N times.

$$CNT\_N = {\sum }_{k = 1}^{N} \frac{T}{{T}_{ROSCk}} \qquad ( 3 )$$

The averaging circuit 443 divides the count CNT_N by N, and outputs the resulting value as the average count C4_{AVE}. In other words, the averaging circuit 443 divides the count CNT_N by N and outputs the resulting value CNT_N/N as a final monitor output value.

As described above, the semiconductor integrated circuit according to the present embodiment can detect an average value representing the variations in the characteristics in a chip by using the monitor circuits disposed at plural locations within the chip. Here, the semiconductor integrated circuit according to the present embodiment controls the oscillation time of the ring oscillator included in each monitor circuit by using the clock pulse signal EN_PULSE alone. Therefore, like the semiconductor integrated circuit according to the first embodiment, the semiconductor integrated circuit according to the present embodiment ensures that the ring oscillators included in the monitor circuits precisely agree in oscillation time. Consequently, the semiconductor integrated circuit according to the present embodiment can monitor the performance of the chip with high accuracy. Further, in the semiconductor integrated circuit according to the present embodiment, all the outputs of the monitor circuits need not be coupled to the summing circuit 44. In other words, the semiconductor integrated circuit according to the present embodiment is configured by merely coupling the output of each monitor circuit to a neighboring monitor circuit. This makes it possible to reduce the overall wiring length.

In the present embodiment, the summing circuit 44 divides the count CNT_N by N and outputs the resulting value CNT_N/N as the monitor output value. However, the present invention is not limited to the use of such a circuit configuration. The present invention can also be applied to a circuit configuration in which the count CNT_N is output as the monitor output value instead of the count CNT_N/N. If such an alternative circuit configuration is employed, the averaging circuit 443 is not required.

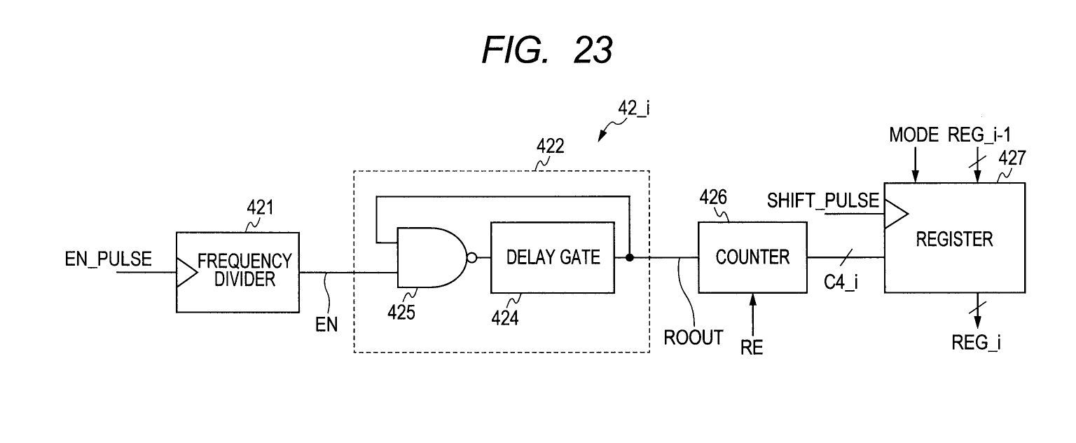

In the present embodiment, it is assumed that the control signal MODE changes the coupling relationship between the included units of the counter 423. However, the present invention is not limited to the use of such a circuit configuration. The present invention can also be applied to a circuit configuration that includes a counter 426 and a register 427 in place of the counter 423 as shown in FIG. 23. The counter 426 counts the oscillations of the oscillation signal ROOUT and outputs the resulting count C4_i to the register 427. When the control signal MODE is 0 (in the count mode), the register 427 fetches the count C4_i. When the control signal MODE is 1 (in the shift mode), the register 427 outputs the count C4_i or the register value REG_i−1 output from the preceding monitor circuit to the succeeding monitor circuit. In other words, the circuit shown in FIG. 23 is configured so that the flip-flop included in the counter 423 is provided as the register 427 external to the counter 423. In this instance, a selector for changing the coupling relationship in accordance with the selected mode need not be provided in a critical path in the counter 426. This makes it possible to improve the speed performance of the counter 426. It means that timing adjustments can be made with ease. Further, any counter can be used in this case because there is no need to use a synchronous counter such as the counter 423.

### Fifth Embodiment

A semiconductor integrated circuit 51 according to a fifth embodiment of the present invention will now be described. The semiconductor integrated circuit 51 differs from the semiconductor integrated circuit 11 according to the first embodiment in that the former includes a control circuit 53 in place of the control circuit 13 and monitor circuits 52_1 to 52_N in place of the monitor circuits 12_1 to 12_N, where N is equal to the k-th power of 2 (k is 0 or a greater integer). The other circuit elements are the same as those used in the first embodiment and will not be redundantly described.

The control circuit 53 outputs the select signal SEL in addition to the reset signal RE and the clock pulse signal EN_PULSE. In the other respects, the control circuit 53 has the same circuit configuration as the control circuit 13. It should be noted that the clock pulse signal EN_PULSE output from the control circuit 53 includes two pulse signals.

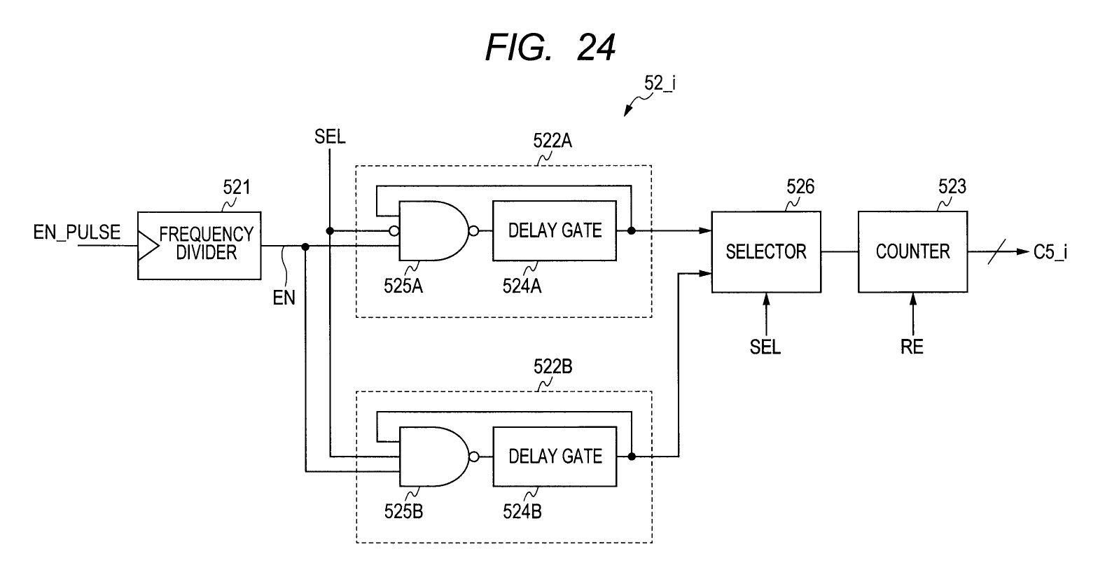

FIG. 24 shows the circuit configuration of a monitor circuit 52-i, where i is an integer between 1 and N. All the N monitor circuits 52_1 to 52_N have the same circuit configuration. The monitor circuit 52_i includes a frequency divider 521, ring oscillators 522A, 5228, a counter 523, and a selector 526. The ring oscillator 522A includes a delay gate 524A and a NAND 525A. The ring oscillator 522B includes a delay gate 5248 and a NAND 5258.

The frequency divider 521 frequency-divides the clock pulse signal EN_PULSE by two, and outputs the resulting frequency-divided signal to the ring oscillators 522A, 522B as the enable signal EN.

The NAND 525A included in the ring oscillator 522A inputs an inverted version of the select signal SEL. The NAND 525B included in the ring oscillator 522B inputs the select signal SEL. Thus, either the ring oscillator 522A or the ring oscillator 522B, whichever is selected by the select signal SEL, oscillates during a period T during which the enable signal EN is 1, and outputs the oscillation signal ROOUT. The ring oscillators 522A, 522B will not be described in detail because they have the same circuit configuration as the ring oscillator 122 used in the first embodiment. The NANDs 525A, 525B correspond to the NAND 125. The delay gates 524A, 524B correspond to the delay gate 124. The number of elements (e.g., inverters) forming the delay gates 524A, 524B is limited to the minimum without affecting their delay time.

The selector 526 selects the oscillation signal ROOUT of a ring oscillator selected by the select signal SEL, and outputs the selected signal to the counter 523. The counter 523 is initialized to a count of 0 by the reset signal RE before the enable signal EN is set to 1. Subsequently, the counter 523 counts the oscillations (pulses) of the oscillation signal ROOUT and outputs the resulting count as a count C5_i.

The elements (e.g., inverters) included in the delay gates 524A, 524B differ in threshold voltage. Therefore, when the select signal SEL is 0, the counter 523 outputs a count T/T_{ROSCA} corresponding to the oscillation cycle T_{ROSCA} of the ring oscillator 522A as the count C5_i. When, on the other hand, the select signal SEL is 1, the counter 523 outputs a count T/T_{ROSCB} corresponding to the oscillation cycle T_{ROSCB} of the ring oscillator 522B as the count C5_i.

As described above, the semiconductor integrated circuit according to the present embodiment can detect an average value representing the variations in the characteristics in a chip by using the monitor circuits disposed at plural locations within the chip. Here, the semiconductor integrated circuit according to the present embodiment controls the oscillation time of the ring oscillator included in each monitor circuit by using the clock pulse signal EN_PULSE alone. Therefore, like the semiconductor integrated circuit according to the first embodiment, the semiconductor integrated circuit according to the present embodiment ensures that the ring oscillators included in the monitor circuits precisely agree in oscillation time. Consequently, the semiconductor integrated circuit according to the present embodiment can monitor the performance of the chip with high accuracy. Further, each monitor circuit includes plural ring oscillators having elements that differ in threshold value. Therefore, even when elements included in a chip differ in threshold voltage, the variations in their characteristics can be accurately detected. In this instance, the area occupied by each monitor circuit is increased merely by one ring oscillator and the selector 526. It means that the increase in the occupied area is minimized.

In the present embodiment, it is assumed that each monitor circuit includes two ring oscillators. However, the present invention is not limited to the use of such a circuit configuration. The present invention can also be applied to a circuit configuration in which each monitor circuit includes any number of ring oscillators. When such an alternative circuit configuration is employed, the number of select signals generated by the control circuit needs to be increased in accordance with the number of ring oscillators.

In the present embodiment, it is also assumed that the number of elements (e.g., inverters) forming the delay gates 524 is limited without affecting their delay time. However, the present invention is not limited to the use of such a circuit configuration. Alternatively, any appropriate number of elements (e.g., inverters) may be used to form the delay gates 524 without affecting their delay time.

### Sixth Embodiment

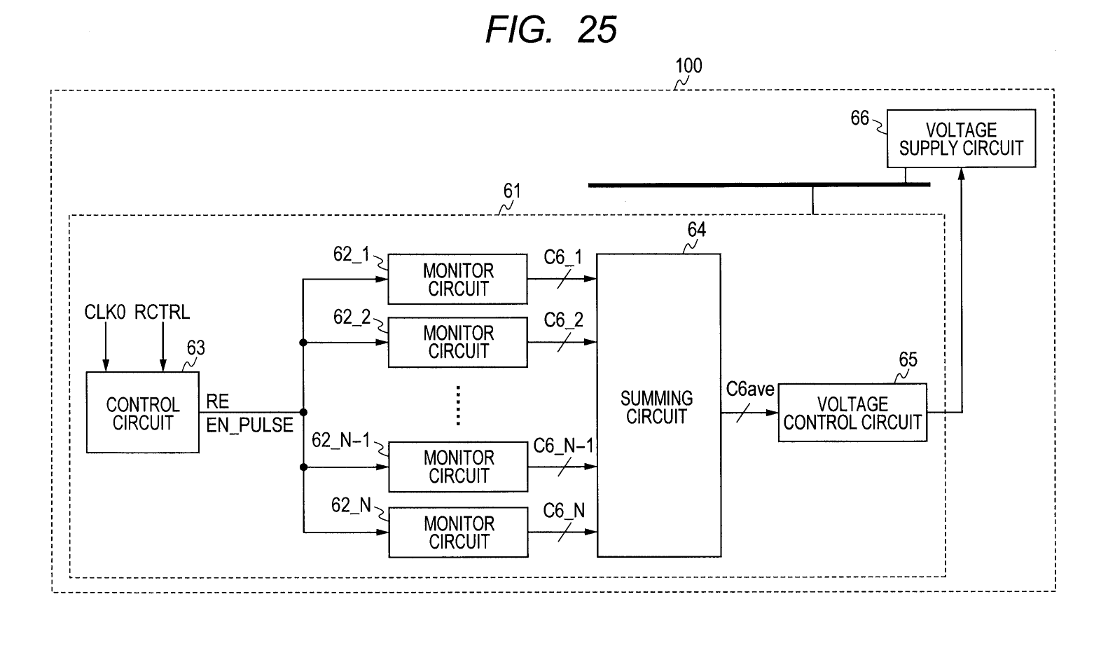

FIG. 25 is a block diagram illustrating a semiconductor integrated circuit (voltage controller) 100 that includes a semiconductor integrated circuit 61 according to a sixth embodiment of the present invention. The circuit shown in FIG. 25 includes the semiconductor integrated circuit 61, which detects the variations in the characteristics of a chip; a voltage supply circuit 66, which supplies a supply voltage VDD to the semiconductor integrated circuit 100; and a peripheral circuit (not shown). The semiconductor integrated circuit 61 includes monitor circuits 62_1 to 62_N, a control circuit 63, a summing circuit 64, and a voltage control circuit 65. The semiconductor integrated circuit 61 differs from the semiconductor integrated circuit 11 according to the first embodiment in that the former additionally includes the voltage control circuit 65. The other circuit elements are the same as those used in the semiconductor integrated circuit 11 and will not be redundantly described.

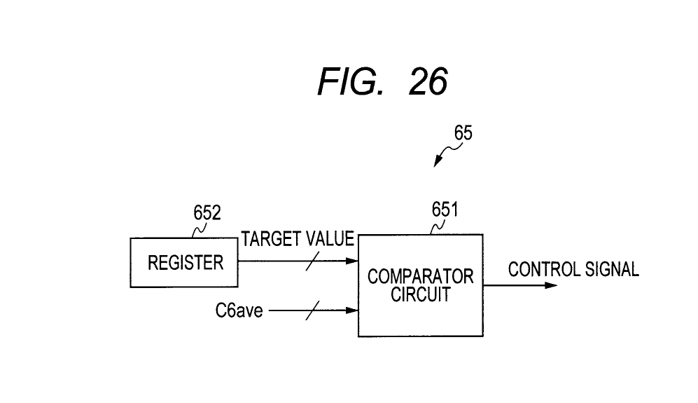

FIG. 26 shows the circuit configuration of the voltage control circuit 65. The voltage control circuit 65 includes a comparator circuit 651 and a register (third register) 652. The register 652 stores a target value (first reference value) for the monitor output value (the result of detection of variations in the characteristics of a chip). The target value is a value that should be output from the summing circuit 64 when, for instance, the process, voltage, and temperature of the chip having the monitor circuits are under specific conditions.

The comparator circuit 651 included in the voltage control circuit 65 compares an average count C6_{AVE}, which is output from the summing circuit 64, against the target value. When the average count C6_{AVE} is greater than the target value, the comparator circuit 651 outputs a control signal (voltage control signal) so as to instruct the voltage supply circuit 66 to lower the supply voltage VDD. When, on the other hand, the average count C6_{AVE} is smaller than the target value, the comparator circuit 651 outputs a control signal so as to instruct the voltage supply circuit 66 to raise the supply voltage VDD.

The voltage supply circuit 66 changes the supply voltage VDD in accordance with a control output generated from the comparator circuit 651. When the monitoring operation by the semiconductor integrated circuit 61 (an operation for detecting the variations in the characteristics of a chip) and the supply voltage VDD control operation by the voltage supply circuit 66 are repeated as described above, the output value (average count C6_{AVE}) generated from the summing circuit 64 eventually converges to the target value.

As described above, the semiconductor integrated circuit according to the present embodiment can detect an average value representing the variations in the characteristics in a chip by using the monitor circuits disposed at plural locations within the chip. Here, the semiconductor integrated circuit according to the present embodiment controls the oscillation time of the ring oscillator included in each monitor circuit by using the clock pulse signal EN_PULSE alone. Therefore, like the semiconductor integrated circuit according to the first embodiment, the semiconductor integrated circuit according to the present embodiment ensures that the ring oscillators included in the monitor circuits precisely agree in oscillation time. Consequently, the semiconductor integrated circuit according to the present embodiment can monitor the performance of the chip with high accuracy. Further, as the semiconductor integrated circuit according to the present embodiment additionally includes the voltage control circuit 65, it can control the supply voltage VDD in accordance with the monitor output value. Thus, the semiconductor integrated circuit according to the present embodiment can accurately cause the performance of the chip to approach the target value.

In the present embodiment, it is assumed that the comparator circuit 651 compares the monitor output value against one target value. However, the present invention is not limited to the use of such a circuit configuration. The present invention can also be applied to a circuit configuration in which the register 652 stores a maximum target value (first reference value) MAX and a minimum target value (second reference value) MIN to let the comparator circuit 651 compare the monitor output value against these target values. If, in such a circuit configuration, the monitor output value is greater than the maximum target value MAX, the comparator circuit 651 outputs a control signal so as to instruct the voltage supply circuit 66 to lower the supply voltage VDD. If, on the other hand, the monitor output value is smaller than the minimum target value MIN, the comparator circuit 651 outputs a control signal so as to instruct the voltage supply circuit 66 to raise the supply voltage VDD. This ensures that the monitor output value is eventually between the maximum target value MAX and the minimum target value MIN. When the above-described alternative circuit configuration is used, the control operation concerning the supply voltage VDD comes to a stop when the monitor output value falls within a predetermined range. This makes it possible to prevent the supply voltage VDD from being varied by subtle changes in the monitor output value.

In the present embodiment, it is also assumed that the counter included in each monitor circuit is capable of counting up to an arbitrary number. Alternatively, however, a counter having a minimum required number of digits may be used as far as it can count up to the maximum target value MAX. If, in this instance, a counter overflow is detected, it is concluded that the monitor output value is greater than the maximum target value MAX. Consequently, the supply voltage can be controlled in the same manner as in the present embodiment. This also makes it possible to reduce the area occupied by the counter.

In the present embodiment, it is also assumed that the voltage control circuit 65 controls the supply voltage VDD of the semiconductor integrated circuit 100 in accordance with the monitor output value. However, the present invention is not limited to the use of such a circuit configuration. The present invention can also be applied to a circuit configuration in which the voltage control circuit 65 controls a substrate bias. When this alternative circuit configuration is used, the voltage supply circuit 66 supplies the substrate bias to the semiconductor integrated circuit 100. If, in this instance, the monitor output value is greater than the target value, the comparator circuit 651 outputs a control signal so as to instruct the voltage supply circuit 66 to deepen the substrate bias. If, on the other hand, the monitor output value is smaller than the target value, the comparator circuit 651 outputs a control signal so as to instruct the voltage supply circuit 66 to shallow the substrate bias. When the above-described alternative circuit configuration is used, the supply voltage VDD is always maintained constant. Therefore, it is not necessary to use a level shifter even when exchanging signals with another chip.

In the present embodiment, the target value is a value that should be output from the monitor circuits when the process, voltage, and temperature of the chip having the monitor circuits are under specific conditions. Alternatively, however, an arbitrary value determined in accordance with the results of design or actual chip testing may be used as the target value.

In the present embodiment, it is also assumed that the voltage control circuit 65 is included in the semiconductor integrated circuit 61. However, the present invention is not limited to the use of such a circuit configuration. The present invention can also be applied to a circuit configuration in which the voltage control circuit 65 is positioned outside the semiconductor integrated circuit 61.

### Seventh Embodiment

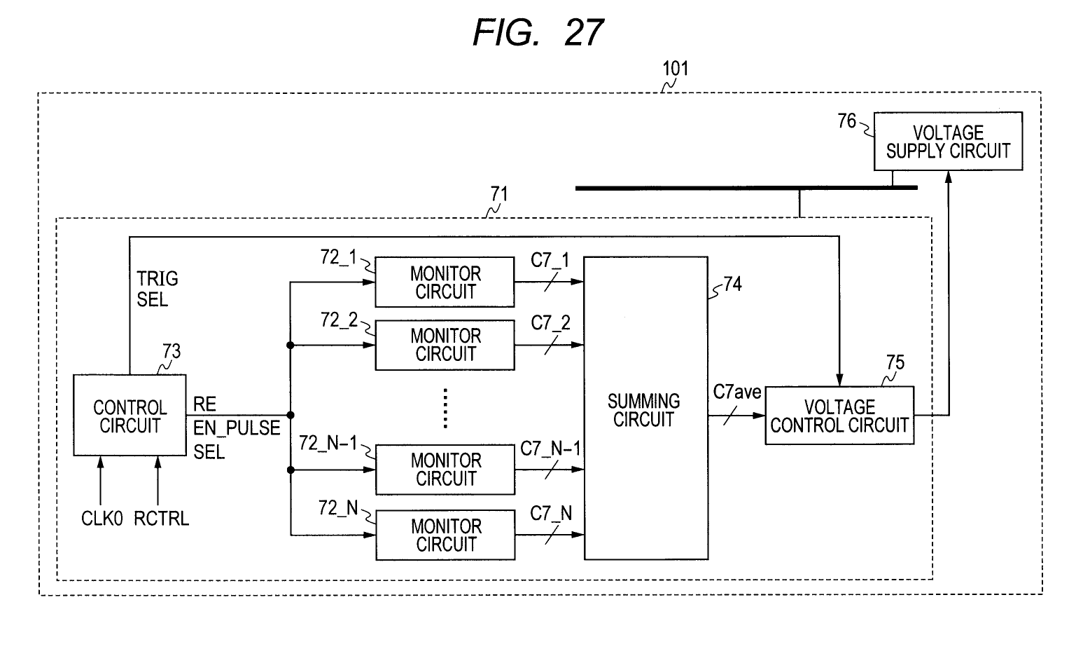

FIG. 27 is a block diagram illustrating a semiconductor integrated circuit (voltage controller) 101 that includes a semiconductor integrated circuit 71 according to a seventh embodiment of the present invention. The circuit shown in FIG. 27 includes the semiconductor integrated circuit 71, which detects the variations in the characteristics of a chip; a voltage supply circuit 76, which supplies a supply voltage VDD to the semiconductor integrated circuit 101; and a peripheral circuit (not shown). The semiconductor integrated circuit 71 includes monitor circuits 72_1 to 72_N, a control circuit 73, a summing circuit 74, and a voltage control circuit 75. The monitor circuits 72_1 to 72_N have the same circuit configuration as those used in the fifth embodiment and will not be redundantly described. In the subsequent description, a frequency divider 721 corresponds to the frequency divider 521; a ring oscillator 722A corresponds to the ring oscillator 522A; a ring oscillator 722B corresponds to the ring oscillator 522B; a selector 726 corresponds to the selector 526; and a counter 723 corresponds to the counter 523.

The control circuit 73 differs from the control circuit 63 in that the former additionally outputs the select signal SEL to the monitor circuits 72_1 to 72_N and additionally outputs the select signal SEL and a trigger signal TRIG to the voltage control circuit 75.

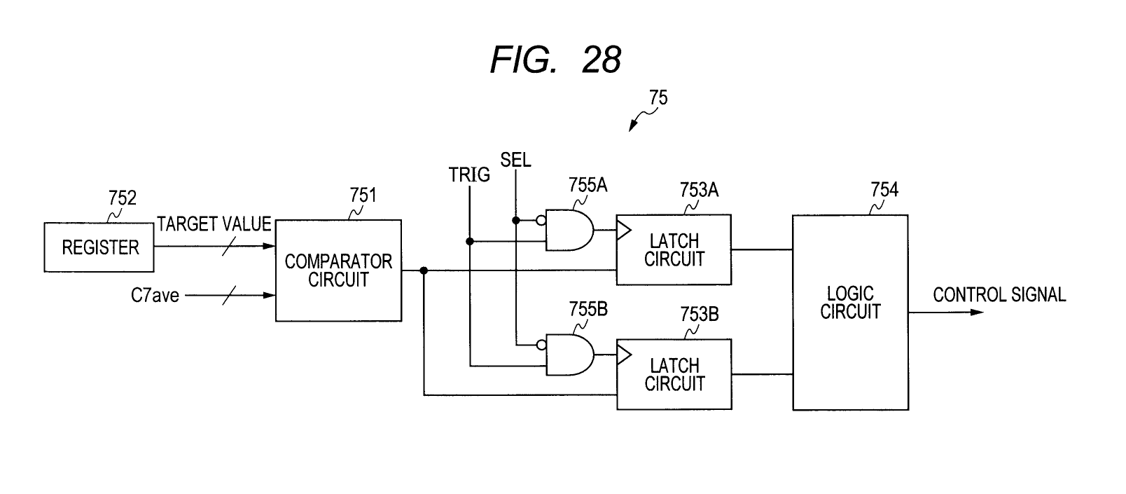

FIG. 28 shows the circuit configuration of the voltage control circuit 75. The voltage control circuit 75 includes a comparator circuit 751, a register 752, latch circuits 753A, 753B, ANDS 755A, 755B, and a logic circuit 754. The register 752 stores as many target values as the number of ring oscillators included in the monitor circuits 72_1 to 72_N. In other words, in the present embodiment, each monitor circuit 72_i includes two ring oscillators as is the case with the fifth embodiment. Thus, the register 752 stores two target values. The target values are values that should be output from the summing circuit 74 when, for instance, the process, voltage, and temperature of the chip having the monitor circuits are under specific conditions.

When the select signal SEL is 0, the latch circuit 753A fetches the result of comparison by the comparator circuit 751 in synchronism with the trigger signal TRIG, and outputs the result of comparison to the logic circuit 754. When, on the other hand, the select signal SEL is 1, the latch circuit 753B fetches the result of comparison by the comparator circuit 751 in synchronism with the trigger signal TRIG, and outputs the result of comparison to the logic circuit 754. The logic circuit 754 then generates a control signal in accordance with the signal output from the latch circuit 753A or the latch circuit 753B, and outputs the control signal to the voltage supply circuit 76.

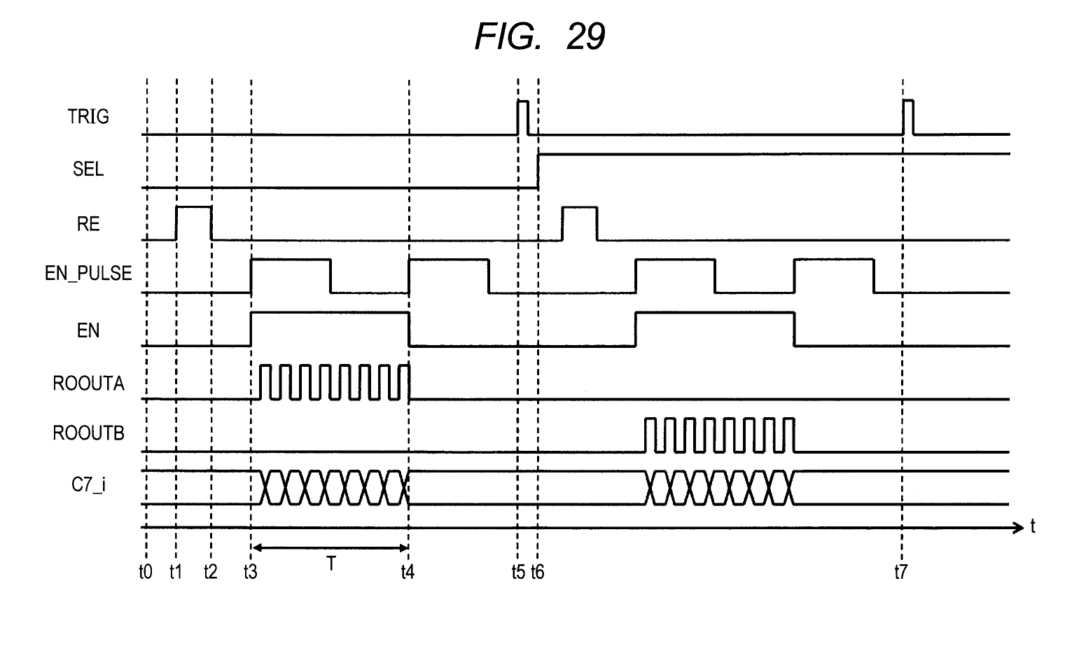

An operation performed by the semiconductor integrated circuit 101 according to the present embodiment will now be described with reference to a timing diagram of FIG. 29. In the initial state t0, the reset signal RE, the clock pulse signal EN_PULSE, and the select signal SEL are all 0.

In the monitor circuit 72_i, the counter 723 is initialized (for a period of time between t1 and t2) when the reset signal RE is 1. Subsequently, the first pulse signal of the clock pulse signal EN_PULSE rises (at time t3). Next, the second pulse signal of the clock pulse signal EN_PULSE rises (at time t4). In the monitor circuit 72_i, the frequency divider 721 outputs an enable signal EN of 1 during a period T between t3 and t4, that is, during a period between the instant at which the clock pulse signal EN_PULSE rises and the instant at which the same signal EN_PULSE rises again. The ring oscillator 722A oscillates during the period T and outputs the oscillation signal ROOUT to the counter 723 through the selector 726. The counter 723 counts the oscillations of the oscillation signal ROOUT during the period T, and outputs the resulting count as a count C7_i. Here, the count C7_i indicates a value T/T_{ROSCi} that corresponds to the oscillation cycle T_{ROSCi} of the ring oscillator 722A (at time t4).

The summing circuit 74 divides the sum of counts C7_1 to C7_N by N, and outputs the resulting value as an average count C7_{AVE}. The comparator circuit 751 compares the average count C7_{AVE}, which is a monitor output value, against the associated target value, and outputs the result of comparison. The latch circuit 753A fetches the result of comparison in synchronism with the trigger signal TRIG, and outputs the result of comparison to the logic circuit 754 (at time t5).

Subsequently, the select signal SEL switches from 0 to 1 (at time t6). After time t6, the same operation is performed as during the period of time between t1 and t5. In the monitor circuit 72_i, however, the ring oscillator 722B oscillates during the period T and outputs an oscillation signal ROOUTB. Further, the comparator circuit 751 compares the average count C7_{AVE}, which is calculated by using the ring oscillator 722B in each monitor circuit 72_1 to 72_N, against the associated target value, and outputs the result of comparison. The latch circuit 753B fetches the result of comparison in synchronism with the trigger signal TRIG and outputs the result of comparison to the logic circuit 754 (at time t7). After the output results of the latch circuits 753A, 753B are put into final form, the logic circuit 754 outputs a control signal to the voltage supply circuit 66 in accordance with their output results (at time t7).

When, for instance, at least either of the monitor output values derived from the ring oscillators 722A, 722B is smaller than the associated target value, the voltage control circuit 75 outputs a control signal so as to instruct the voltage supply circuit 76 to raise the supply voltage. When, on the other hand, the monitor output values derived from the ring oscillators 722A, 722B are both greater than the associated target value, the voltage control circuit 75 outputs a control signal so as to instruct the voltage supply circuit 76 to lower the supply voltage. The voltage supply circuit 76 changes the supply voltage VDD in accordance with the control signal output from the voltage control circuit 75. When the monitoring operation by the semiconductor integrated circuit 71 and the supply voltage VDD control operation by the voltage supply circuit 76 are repeated as described above, the output value (average count C7_{AVE}) generated from the summing circuit 74 eventually converges to the target value.

As described above, the semiconductor integrated circuit according to the present embodiment can detect an average value representing the variations in the characteristics in a chip by using the monitor circuits disposed at plural locations within the chip. Here, the semiconductor integrated circuit according to the present embodiment controls the oscillation time of the ring oscillator included in each monitor circuit by using the clock pulse signal EN_PULSE alone. Therefore, like the semiconductor integrated circuit according to the first embodiment, the semiconductor integrated circuit according to the present embodiment ensures that the ring oscillators included in the monitor circuits precisely agree in oscillation time. Consequently, the semiconductor integrated circuit according to the present embodiment can monitor the performance of the chip with high accuracy. Further, as the semiconductor integrated circuit according to the present embodiment additionally includes the voltage control circuit 75, it can control the supply voltage VDD in accordance with the monitor output value. Thus, the semiconductor integrated circuit according to the present embodiment can accurately cause the performance of the chip to approach the target value. In addition, even when the chip includes plural elements differing in threshold voltage, the semiconductor integrated circuit according to the present embodiment makes it possible to control the supply voltage in accordance with their variations.

In the present embodiment, it is assumed that the number of elements (e.g., inverters) forming the delay gate included in the ring oscillator is limited without affecting the delay time. However, the present invention is not limited to the use of such a circuit configuration. Further, the number of gates may be determined in such a manner that the ring oscillators 722A, 722B have the same oscillation cycle. Such an alternative circuit configuration eliminates the necessity of preparing a target value for each ring oscillator. Therefore, the use of only one target value will be adequate for subjecting the monitor output value derived from each ring oscillator to comparison.

In the present embodiment, it is also assumed that the voltage control circuit 75 is included in the semiconductor integrated circuit 71. However, the present invention is not limited to the use of such a circuit configuration. The present invention can also be applied to a circuit configuration in which the voltage control circuit 75 is positioned outside the semiconductor integrated circuit 71.

The difference between the present invention and the related art disclosed in Japanese Unexamined Patent Publication No. 2002-100967 will now be described. The related art disclosed in Japanese Unexamined Patent Publication No. 2002-100967 has a circuit configuration for providing voltage control to ensure that the “interval between two pulse signals” agrees with the “delay time within a monitor circuit.” Meanwhile, the present invention has a circuit configuration that divides the “interval between two pulse signals (e.g., time T)” by the “delay time within a monitor circuit (e.g., T_{ROSC})” and outputs the resulting value as a monitor output value. Both of these two circuit configurations essentially compare the “interval between two pulse signals” with the “delay time within a monitor circuit.” The “delay time within a monitor circuit” is the delay time that is determined by the characteristics of a reference delay element shown at 332 and 335 in FIG. 16 in the Japanese Unexamined Patent Publication No. 2002-100967. It corresponds to the delay time that is determined by the characteristics of the ring oscillator included in a monitor circuit used in an embodiment of the present invention.

In the semiconductor integrated circuit disclosed in Japanese Unexamined Patent Publication No. 2002-100967, a pulse generator circuit 32 (see FIG. 15 in the Japanese Unexamined Patent Publication No. 2002-100967) generates a pulse signal S32 and outputs the pulse signal to a monitor circuit 33 (see FIG. 15 in the Japanese Unexamined Patent Publication No. 2002-100967) and a delay detector circuit 34 (see FIG. 15 in the Japanese Unexamined Patent Publication No. 2002-100967). More specifically, the pulse generator circuit 32 outputs a pulse signal for starting the measurement of “monitor circuit internal delay time” to the monitor circuit 33, and outputs a pulse signal for terminating the measurement of “monitor circuit internal delay time” to the delay detector circuit 34. Thus, these pulse signals flow in different signal paths. The “monitor circuit internal delay time” is then detected as the time lag between the pulse signal S32 input into the monitor circuit 33 and the pulse signal S33 input into the delay detector circuit 34. In this instance, delay elements (1) and (2) below are added as the “monitor circuit internal delay time.”

(1) Wiring delay caused by a long layout distance between the monitor circuit and the delay detector circuit
(2) Delay caused by a signal input/output process in the monitor circuit (e.g., delay caused by buffering and a time lag between clock input into a counter and counter output finalization)

Meanwhile, in the semiconductor integrated circuit according to an embodiment of the present invention, a monitor circuit includes a frequency divider (see, for instance, FIG. 3) so that the clock pulse signal EN_PULSE, which includes two pulses for timing the start and termination of measurement, is supplied to the frequency divider. It means that the pulse signals for timing the start and termination of measurement are supplied through the same signal path. Therefore, the present invention makes it possible to accurately compare the “delay time within a monitor circuit” with the “interval between two pulse signals” without being affected by delay elements (1) and (2) above. The same also holds true for the difference between the present invention and the related art disclosed in Japanese Unexamined Patent Publication No. 2005-045172.

While the present invention has been described in terms of preferred embodiments, it should be understood that the present invention is not limited to those preferred embodiments. Persons of skill in the art will appreciate that variations may be made without departure from the scope and spirit of the present invention. In the embodiments described above, it is assumed that a monitor circuit includes a ring oscillator. However, the present invention is not limited to the use of such a circuit configuration. The present invention can also be applied to a circuit configuration in which an oscillator circuit other than a ring oscillator is used.

1. A semiconductor integrated circuit comprising:
a first monitor circuit;
a control circuit that generates a control signal having M successive pulses (M is 2 or a greater integer) and outputs the control signal to the first monitor circuit;
wherein the first monitor circuit includes:
a frequency divider circuit that frequency-divides the control signal by M and generates the resulting signal as an enable signal; and
an oscillator circuit that generates an oscillation signal as a monitor output value during a period defined in accordance with the enable signal.

2. The semiconductor integrated circuit according to claim 1, wherein the control circuit outputs the control signal having a cycle proportional to a cycle of an input clock signal.

3. The semiconductor integrated circuit according to claim 1 or 2, further comprising:
a second monitor circuit that has the same circuit configuration as a configuration of the first monitor circuit;
wherein the control circuit outputs the control signal to the first monitor circuit and the second monitor circuit.

4. The semiconductor integrated circuit according to claim 3, further comprising:
a summing circuit that generates an average monitor output value by averaging the number of oscillations of an oscillator circuit included in the first monitor circuit and the number of oscillations of an oscillator circuit included in the second monitor circuit.

5. The semiconductor integrated circuit according to claim 1 or 2, wherein the first monitor circuit additionally includes a counter that counts the number of oscillations of the oscillator circuit and generates a monitor output value indicative of the resulting count in place of the oscillation signal.

6. The semiconductor integrated circuit according to claim 4,
wherein the first monitor circuit and the second monitor circuit further include a counter that counts the number of oscillations of the oscillator circuit and generates a monitor output value indicative of the resulting count in place of the oscillation signal; and
wherein the summing circuit generates the average monitor output value in accordance with monitor output values generated respectively from the first monitor circuit and the second monitor circuit.

7. The semiconductor integrated circuit according to claim 4,
wherein the first monitor circuit and the second monitor circuit further include a counter that counts the number of oscillations of the oscillator circuit and generates a monitor output value indicative of the resulting count in place of the oscillation signal;
wherein the second monitor circuit generates a monitor output value in accordance with the number of oscillations of the oscillator circuit included in the second monitor circuit and with a monitor output value generated from the first monitor circuit; and
wherein the summing circuit generates the average monitor output value in accordance with the monitor output value generated from the second monitor circuit.

8. The semiconductor integrated circuit according to claim 7, wherein the control circuit outputs the control signal to the second monitor circuit after outputting the control signal to the first monitor circuit.

9. The semiconductor integrated circuit according to claim 7,
wherein the first monitor circuit additionally includes a first register;
wherein the second monitor circuit additionally includes a second register; wherein the control circuit additionally generates a trigger signal that drives the first register and the second register;
wherein, in a count mode, the first register stores the number of oscillations of an oscillator circuit included in the first monitor circuit in synchronism with the trigger signal while the second register stores the number of oscillations of an oscillator circuit included in the second monitor circuit in synchronism with the trigger signal; and
wherein, in a shift mode, the first register outputs a stored value to the second register in synchronism with the trigger signal while the second register outputs a stored value to the summing circuit in synchronism with the trigger signal.

10. The semiconductor integrated circuit according to claim 4, wherein the summing circuit includes a selector that sequentially selects and outputs the oscillation signals of oscillator circuits included in the first monitor circuit and the second monitor circuit, a counter that counts the number of oscillations of an oscillation signal selected by the selector, and an averaging circuit that generates the average monitor output value in accordance with the count reached by the counter.

11. The semiconductor integrated circuit according to claim 1, wherein the oscillator circuit is a ring oscillator.

12. The semiconductor integrated circuit according to claim 11, wherein the first monitor circuit includes a plurality of the ring oscillators that have elements differing in threshold voltage.

13. A voltage controller comprising:
the semiconductor integrated circuit according to claim 1;
a voltage control circuit that generates a voltage control signal in accordance with a monitor output value of the semiconductor integrated circuit; and
a voltage supply circuit that controls a voltage to be supplied to the semiconductor integrated circuit in accordance with the voltage control signal.

14. The voltage controller according to claim 13, wherein the voltage control circuit includes a third register that stores a first reference value, and a comparator circuit that compares the monitor output value against the first reference value and generates the voltage control signal.

15. The voltage controller according to claim 14,
wherein the third register stores a second reference value in addition to the first reference value; and
wherein the comparator circuit generates the voltage control signal so as to ensure that the monitor output value is between the first reference value and the second reference value.

16. The voltage controller according to any one of claims 13 to 15, wherein the voltage supplied from the voltage supply circuit is a supply voltage.

17. The voltage controller according to any one of claims 13 to 15, wherein the voltage supplied from the voltage supply circuit is a substrate bias.
